(19) United States
(12) Patent Application Publication
(10) Pub. No.: US 2026/0150647 A1
(43) Pub. Date: May 28, 2026

(54) MEMORY DEVICE WITH BACKSIDE CONTACTS FOR SIGNAL ROUTING

(71) Applicant: Taiwan Semiconductor Manufacturing Company, Ltd., Hsin-Chu (TW)

(72) Inventors: Shih-Hao Lin, Hsinchu (TW); Jui-Lin Chen, Taipei City (TW); Ping-Wei Wang, Hsinchu (TW); Yu-Bey Wu, Hsinchu City (TW)

(21) Appl. No.: 19/215,911

(22) Filed: May 22, 2025

Related U.S. Application Data
(60) Provisional application No. 63/725,368, filed on Nov. 26, 2024.

(51) Int. Cl. H01L 23/528; G11C 5/06; H10B 10/00; H10D 30/00; H10D 30/01; H10D 30/43

(52) U.S. Cl. CPC H10W 20/427; G11C 5/063; H10B 10/12; H10D 30/014; H10D 30/0191; H10D 30/43; H10D 30/502; H10W 20/43; H10W 20/435

(57) ABSTRACT

A memory cell includes an active region extending lengthwise along a first direction and first and second gate structures extending lengthwise along a second direction different from the first direction. The first gate structure engages the active region in forming a first transistor, and the second gate structure engages the active region in forming a second transistor. The memory cell further includes a first epitaxial feature disposed on a source region of the first transistor, a second epitaxial feature disposed on a common drain region of the first and second transistors, a backside contact disposed under and in electrical coupling with the first epitaxial feature, a backside signal line disposed under and in electrical coupling with the backside contact, and a first frontside contact disposed above and in electrical coupling with the second epitaxial feature.

### PRIORITY DATA

This application claims priority to U.S. Provisional Ser. No. 63/725,368 filed on Nov. 26, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

In deep sub-micron integrated circuit technology, static random-access memory (SRAM) device has become a popular storage unit of high-speed communication, image processing, and system-on-chip (SOC) products. The amount of embedded SRAM devices in microprocessors and SOCs increases to meet the performance requirement in new technology generations. As silicon technology continues to scale, conventional SRAM devices and the fabrication thereof encounter increasing limitations. For example, the aggressive reduction of IC dimensions has led to densely packed source/drain features, source/drain contacts, gate structures, and gate vias. In some SRAM devices, a multilayer interconnect structure provides metal lines for interconnecting power and signal lines within and between memory cells, forming over the source/drain contacts and gate vias of the transistors. As device sizes shrink and transistor density increases, certain source/drain contacts (e.g., those used for signal routing) are placed in close proximity to adjacent gate structures and gate vias, which can result in increased parasitic capacitance, narrowed process windows, and degraded memory device performance. All these issues present performance, yield, and cost challenges. Therefore, while existing SRAM devices may be generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B illustrate a perspective view and a top view of a portion of a memory device, respectively, in accordance with some embodiments of the present disclosure.

FIG. 2 illustrates a cross-sectional view of various layers of a memory device, in accordance with some embodiments of the present disclosure.

FIG. 3 illustrates a circuit schematic of a static random-access memory (SRAM) cell, in accordance with some embodiments of the present disclosure.

FIG. 4 illustrates a layout of the SRAM cell as in FIG. 3, in accordance with some embodiments of the present disclosure.

FIG. 5 illustrates a layout of frontside features of a 2×2 SRAM array, in accordance with some embodiments of the present disclosure.

FIG. 6 illustrates a layout of backside features of a 2×2 SRAM array, in accordance with some embodiments of the present disclosure.

FIG. 7 illustrates an alternative layout of backside features of a 2×2 SRAM array, in accordance with some embodiments of the present disclosure.

FIG. 8 shows a flow chart of a method for forming an integrated circuit having a plurality of SRAM cells, in accordance with some embodiments of the present disclosure.

FIGS. 9, 10, 11, 12, 13, 14, 15, 16, 17, 18, 19, 20, 21, 22, 23, 24, 25, 26, 27, 28, 29, 30, and 31 illustrate cross-sectional views of an integrated circuit having SRAM cells during fabrication processes according to the method of FIG. 8, in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure generally relates to semiconductor devices and fabrication methods thereof, and more particularly to embodiments of a memory device, such as a static random-access memory (SRAM) device, incorporating certain contacts for signal routing and corresponding signal lines on the backside of the SRAM device. By relocating these contacts to the backside, the distance between the contacts and adjacent gate structures and gate vias is increased, thereby reducing parasitic capacitance and expanding process windows. This reduction in parasitic capacitance enhances signal integrity and improves overall device performance, including faster signal propagation and lower power consumption.

SRAM is an electronic data storage device implemented on a semiconductor-based integrated circuit and generally has much faster access times than other types of data storage technologies. SRAM is popular in high-speed communication, image processing and system-on-chip (SOC) applications. A bit can be read from or written into an SRAM cell within a few nanoseconds. An SRAM cell include transistors with metal interconnect structures above the transistors. The metal interconnect structures include metal lines for interconnecting transistor gates and source/drain regions, such as signal lines for routing bit line and word line signals to the cell components, as well as power rails (such as metal lines for power voltage and electrical ground) for providing power to the cell components. Contacts electrically connect the cell components to the signal lines and the power rails. For example, some of the source/drain regions in an SRAM cell are coupled to bit lines through source/drain contacts. Source/drain region(s) may refer to a source or a drain, individually or collectively dependent upon the context.

Conventionally, SRAM devices are constructed in a stacked-up configuration, with transistors at the lowest level and interconnect structures (including contacts, vias, and metal lines) positioned above the transistors to establish electrical connectivity. Signal lines, such as bit lines, are also located above the transistors and may be integrated into the interconnect structures, electrically coupled to the transistors through contacts. As SRAM device scaling continues to shrink, the available layout area becomes increasingly constrained, reducing the distance between contacts coupled to the bit lines and adjacent gate structures. This reduction in distance leads to increased parasitic capacitance loaded on the bit lines, which has become a challenge in enhancing SRAM performance. Accordingly, while existing semiconductor fabrication approaches have been generally effective, they are not entirely satisfactory in addressing all aspects of SRAM design. One particular area of interest is the separation of contacts coupled to bit lines from adjacent gate structures. Some exemplary embodiments of the present disclosure address this issue by relocating certain contacts and associated bit lines to the backside of the SRAM cells.

Some exemplary embodiments are related to, but not otherwise limited to, multi-gate devices. Multi-gate devices have been introduced in an effort to improve gate control by increasing gate-channel coupling, reduce OFF-state current, and reduce short-channel effects (SCEs). One such multi-gate device that has been introduced is the fin-like field-effect transistor (FinFET). The FinFET gets its name from the fin-like structure which extends from a substrate on which it is formed, and which is used to form the FET channel. Another multi-gate device, introduced in part to address performance challenges associated with the FinFET, is the gate-all-around (GAA) transistor. The GAA transistor gets its name from the gate structure which can extend around the channel region (e.g., a stack of nanosheets) providing access to the channel on four sides. The GAA transistor is compatible with conventional complementary metal-oxide-semiconductor (CMOS) processes and its structure allows it to be aggressively scaled while maintaining gate control and mitigating SCEs. The following disclosure will continue with one or more GAA examples to illustrate various embodiments of the present disclosure. It is understood, however, that the application should not be limited to a particular type of device, except as specifically claimed. For example, aspects of the present disclosure may also apply to implementation based on FinFETs or planar FETs.

The details of the device structures of the present disclosure are described in the attached drawings. The drawings have outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

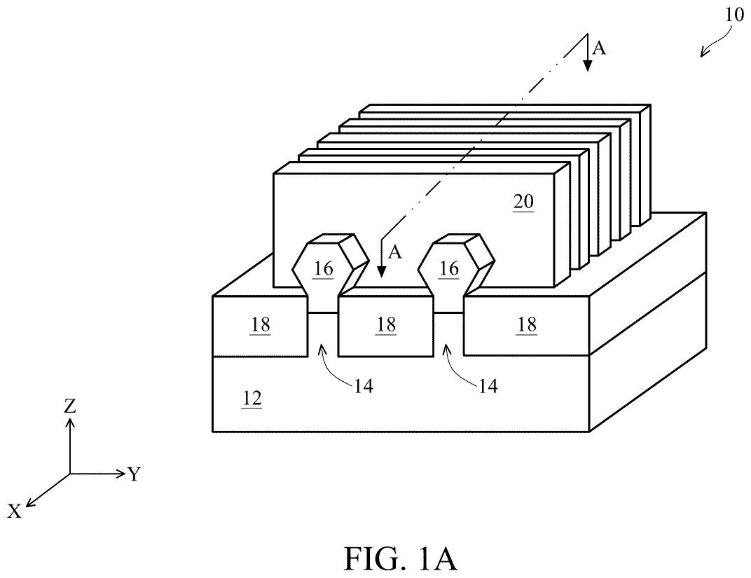

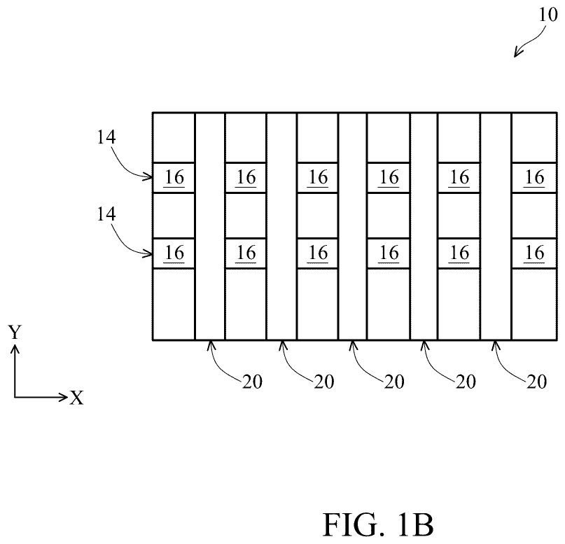

FIGS. 1A and 1B illustrate a perspective view and a top view, respectively, of a portion of an Integrated Circuit (IC) device 10, such as an SRAM device, that is implemented using multi-gate transistors, such as GAA transistors. Referring to FIG. 1A, the IC device 10 includes a substrate 12. The substrate 12 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 12 may be a single-layer material having a uniform composition. Alternatively, the substrate 12 may include multiple material layers having similar or different compositions suitable for IC device manufacturing. In one example, the substrate 12 may be a silicon-on-insulator (SOI) substrate having a semiconductor silicon layer formed on a silicon oxide layer. In another example, the substrate 12 may include a conductive layer, a semiconductor layer, a dielectric layer, other layers, or combinations thereof. Various doped regions, such as source/drain regions, may be formed in or on the substrate 12. The doped regions may be doped with n-type dopants, such as phosphorus or arsenic, and/or p-type dopants, such as boron, depending on design requirements. The doped regions may be formed directly on the substrate 12, in a p-well structure, in an n-well structure, in a dual-well structure, or using a raised structure. Doped regions may be formed by implantation of dopant atoms, in-situ doped epitaxial growth, and/or other suitable techniques.

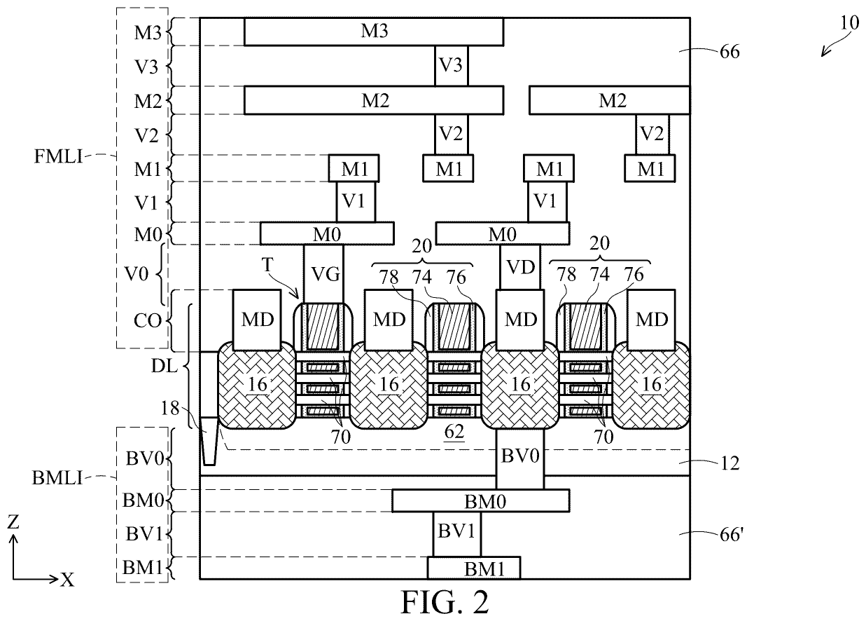

Three-dimensional active regions 14 are formed on the substrate 12. An active region for a transistor refers to the area where a source region, a drain region, and a channel region under a gate structure of the transistor are formed. An active region is also referred to as an “oxide-definition (OD) region” in the context. Each of the active regions 14 includes elongated nanostructures 70 (as shown in FIG. 2) vertically stacked in channel regions defined in the active region and above a fin-shape base. The fin-shape base protrudes upwardly out of the substrate 12. Source/drain features 16 are formed in source/drain regions defined in the active region and over the fin-shape base. The source/drain features 16 abut two opposing ends of the nanostructures 70. The source/drain features 16 may include epi-layers that are epitaxially grown on the fin-shape base.

The IC device 10 further includes isolation structures (or isolation features) 18 formed over the substrate 12. The isolation structures 18 electrically separate various components of the IC device 10. The isolation structures 18 may include silicon oxide, silicon nitride, silicon oxynitride, fluoride-doped silicate glass (FSG), a low-k dielectric material, and/or other suitable materials. In some embodiments, the isolation structures 18 may include shallow trench isolation (STI) features. In one embodiment, the isolation structures 18 are formed by etching trenches in the substrate 12 during the formation of the active regions 14. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 18. Alternatively, the isolation structures 18 may include a multi-layer structure, for example, having one or more thermal oxide liner layers.

The IC device 10 also includes gate structures (or gate stacks) 20 formed over and engaging channel regions in the active regions 14. The gate structures 20 may be dummy gate structures (e.g., containing an oxide gate dielectric and a polysilicon gate electrode), or they may be high-k metal gate (HKMG) structures that contain a high-k gate dielectric and a metal gate electrode, where the HKMG structures are formed by replacing the dummy gate structures. Though not depicted herein, the gate structures 20 may include additional material layers, such as an interfacial layer, a capping layer, other suitable layers, or combinations thereof.

Referring to FIG. 1B, multiple active regions 14 are oriented lengthwise along the X-direction, and multiple gate structures 20 are oriented lengthwise along the Y-direction, i.e., generally perpendicular to the active regions 14. At intersections of the active regions 14 and the gate structures 20, transistors are formed. In many embodiments, the IC device 10 includes additional features such as gate spacers disposed along sidewalls of the gate structures 20, and numerous other features.

FIG. 2 is a fragmentary diagrammatic cross-sectional view of various layers (levels) that can be fabricated over and under a semiconductor substrate (or wafer) to form a portion of a memory device, such as IC chip 10 of FIGS. 1A and 1B, according to various aspects of the present disclosure. As represented in FIG. 2, the various layers include a device layer DL, a frontside multilayer interconnect structure FMLI disposed over the device layer DL, and a backside multilayer interconnect structure BMLI disposed under the device layer DL.

Device layer DL includes devices (e.g., transistors, resistors, capacitors, and/or inductors) and/or device components (e.g., doped wells, gate structures, and/or source/drain features). In embodiments represented by FIG. 2, the device layer DL includes substrate 12, doped regions 62 (e.g., n-wells and/or p-wells) disposed in substrate 12, isolation structures 18, and transistors T. In the depicted embodiment, transistors T include suspended channel layers (nanostructures) 70 and gate structures 20 disposed between source/drain features 16, where gate structures 20 wrap and/or surround suspended channel layers 70. Each gate structure 20 has a metal gate stack formed from a gate electrode 74 disposed over a gate dielectric layer 76 and gate spacers 78 disposed along sidewalls of the metal gate stack.

Multilayer interconnect structures FMLI and BMLI electrically couple various devices and/or components of device layer DL, such that the various devices and/or components can operate as specified by design requirements for the memory device. Each of the multilayer interconnect structures FMLI and BMLI may include one or more interconnect layers. In the depicted embodiment, the multilayer interconnect structure FMLI includes a contact interconnect layer (CO level), a via zero interconnect layer (V0 level), a metal zero interconnect layer (M0level), a via one interconnect layer (V1 level), a metal one interconnect layer (M1 level), a via two interconnect layer (V2 level), a metal two interconnect layer (M2 level), a via three interconnect layer (V3 level), and a metal three interconnect layer (M3 level). Each of the CO level, V0 level, M0 level, V1 level, M1 level, V2 Level, M2 level, V3 level, and M3 level may be referred to as a metal level. Metal lines formed at the M0 level may be referred to as M0 metal lines. Similarly, via or metal lines formed at the V1 level, M1 level, V2 level, M2 level, V3 level, and M3 level may be referred to as V1 vias, M1 metal lines, V2 vias, M2 metal lines, V3 vias, and M3 metal lines, respectively. The present disclosure contemplates multilayer interconnect structure FMLI having more or less interconnect layers and/or levels, for example, a total number of N interconnect layers (levels) of the multilayer interconnect structure FMLI with N as an integer ranging from 1 to 10. Each level of multilayer interconnect structure FMLI includes conductive features (e.g., metal lines, metal vias, and/or metal contacts) disposed in one or more dielectric layers (e.g., an interlayer dielectric (ILD) layer and an etch stop layer (ESL)). The dielectric layers of the multilayer interconnect structure FMLI are collectively referred to as a dielectric structure 66. In some embodiments, conductive features at a same level of multilayer interconnect structure FMLI, such as M0 level, are formed simultaneously. In some embodiments, conductive features at a same level of multilayer interconnect structure FMLI have top surfaces that are substantially planar with one another and/or bottom surfaces that are substantially planar with one another.

In embodiments represented by FIG. 2, the CO level includes source/drain contacts MD disposed in the dielectric structure 66. The source/drain contacts MD may be formed on and in direct contact with silicide layers disposed directly on the source/drain features 16. The V0 level includes gate vias VG disposed on the gate structures and source/drain contact vias VD disposed on the source/drain contacts MD, where gate vias VG connect gate structures to M0 metal lines, source/drain vias V0 connect source/drain contacts MD to M0 metal lines. In some embodiments, the V0 level may also include butted contacts disposed in the dielectric structure 66. The V1 level includes V1 vias disposed in the dielectric structure 66, where V1 vias connect M0 metal lines to M1 metal lines. M1 level includes M1 metal lines disposed in the dielectric structure 66. V2 level includes V2 vias disposed in the dielectric structure 66, where V2 vias connect M1 metal lines to M2 metal lines. M2 level includes M2 metal lines disposed in the dielectric structure 66. V3 level includes V3 vias disposed in the dielectric structure 66, where V3 vias connect M2 metal lines to M3 metal lines.

In the depicted embodiment, the multilayer interconnect structure BMLI includes a backside via zero interconnect layer (BV0 level), a backside metal zero level (BM0 level), a backside via one interconnect layer (BV1 level) and a backside metal one interconnect layer (BM1 level). Each of the BV0 level, BM0 level, BV1 level, and BM1 level may be referred to as a metal level. Metal lines formed at the BM0 level may be referred to as BM0 metal lines. Similarly, via or metal lines formed at the BV0 level, BV1 level, and BM1 level may be referred to as BV0 vias, BV1 vias, and BM1 metal lines, respectively. The present disclosure contemplates multilayer interconnect structure BMLI having more or less interconnect layers and/or levels, for example, a total number of M interconnect layers (levels) of the multilayer interconnect structure BMLI with M as an integer ranging from 1 to 10. Each level of multilayer interconnect structure BMLI includes conductive features (e.g., metal lines, metal vias, and/or metal contacts) disposed in one or more dielectric layers (e.g., an interlayer dielectric (ILD) layer and an etch stop layer (ESL)). The dielectric layers of the multilayer interconnect structure BMLI are collectively referred to as a backside dielectric structure 66′. In some embodiments, conductive features at a same level of multilayer interconnect structure BMLI, such as BM0 level, are formed simultaneously. In some embodiments, conductive features at a same level of multilayer interconnect structure BMLI have top surfaces that are substantially planar with one another and/or bottom surfaces that are substantially planar with one another.

In embodiments represented by FIG. 2, the BV0 level includes vias BV0 formed under the device layer DL. For example, the vias BV0 may include one or more backside source/drain vias (also referred to as backside source/drain contacts) formed directly under the source/drain features of the device layer DL and coupled to those source/drain features by way of a silicide layer. The vias BV0 may include one or more backside gate vias formed directly under and in direct contact with the gate structure(s) of the device layer DL. The BM0 level includes BM0 metal lines formed under the BV0 level. The backside gate vias connect gate structures to BM0 metal lines, and the backside source/drain vias connect source/drain features to BM0 metal lines. The BV1 level includes BV1 vias disposed in the backside dielectric structure 66′, where BV1 vias connect BM0 metal lines to BM1 metal lines. The BM1 level includes BM1 metal lines formed under the BV1 level.

FIG. 2 has been simplified for the sake of clarity to better understand the inventive concepts of the present disclosure. Additional features can be added in the various layers of the memory, and some of the features described can be replaced, modified, or eliminated in other embodiments of the memory. FIG. 2 is merely an example and may not reflect an actual cross-sectional view of the IC chip 10 and/or the SRAM cells 100 that are described in further detail below.

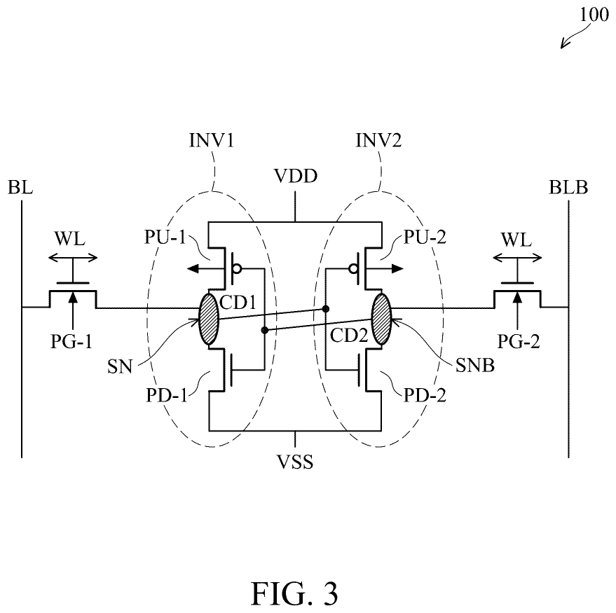

Referring now to FIG. 3, an example circuit schematic for an SRAM cell 100 is shown. The SRAM cell 100 includes two inverters cross-coupled together to store a bit of data and further includes a pass gate electrically connected to the two inverters for reading from and write into the SRAM cell. FIG. 3 has been simplified for the sake of clarity to better understand the inventive concepts of the present disclosure. Additional features can be added in the SRAM cell 104, and some of the features described below can be replaced, modified, or eliminated in other embodiments of the SRAM cell 100.

The exemplary SRAM cell 100 includes six transistors: a pass-gate transistor PG-1, a pass-gate transistor PG-2, a pull-up transistor PU-1, a pull-up transistor PU-2, a pull-down transistor PD-1, and a pull-down transistor PD-1. The exemplary SRAM cell 100 is thus referred to as a 6-transistor (6-T) SRAM cell. The 6-T SRAM cell is used for illustration and to explain the features, but does not limit the embodiments or the appended claims. This non-limiting embodiment may be further extended to an 8-T SRAM cell, a 10-T SRAM cell, and to content addressable memory (CAM) cells.

Further, the exemplary SRAM cell 100 is a single-port SRAM cell that includes a write-port, which is used for illustration and to explain the features, but does not limit the embodiments or the appended claims. This non-limiting embodiment may be further extended to a multi-port SRAM cell, such as a two-port SRAM cell that includes a write-port and a read-port.

In operation, the pass-gate transistors PG-1, PG-2 provide access to a storage portion of the SRAM cell 100, which includes a cross-coupled pair of inverters, a first inverter INV1 and a second inverter INV2. The first inverter INV1 includes the pull-up transistor PU-1 and the pull-down transistor PD-1, and the second inverter INV2 includes the pull-up transistor PU-2 and the pull-down transistor PD-2.

A gate of the pull-up transistor PU-1 interposes a source (electrically coupled with a power voltage line or referred to as a VDD line) and a first common drain (CD1), and a gate of the pull-down transistor PD-1 interposes a source (electrically coupled with an electrical ground line or referred to as a VSS line) and the first common drain (CD1). A gate of the pull-up transistor PU-2 interposes a source (electrically coupled with the VDD line) and a second common drain (CD2), and a gate of the pull-down transistor PD-2 interposes a source (electrically coupled with the VSS line) and the second common drain (CD2). In some implementations, the first common drain (CD1) is a storage node (SN) that stores data in true form, and the second common drain (CD2) is a storage node (SNB) that stores data in complementary form. The gate of the pull-up transistor PU-1 and the gate of the pull-down transistor PD-1 are coupled with the second common drain (CD2), and the gate of the pull-up transistor PU-2 and the gate of the pull-down transistor PD-2 are coupled with the first common drain (CD1). A gate of the pass-gate transistor PG-1 interposes a source (electrically coupled with a bit line BL) and a drain, which is electrically coupled with the first common drain (CD1). A gate of the pass-gate transistor PG-2 interposes a source (electrically coupled with a complementary bit line BLB) and a drain, which is electrically coupled with the second common drain (CD2). For simplicity, the bit line BL and complementary bit line BLB may be collectively refer to as bit lines dependent upon the context. The gates of the pass-gate transistors PG-1, PG-2 are electrically coupled with a word line WL. In some implementations, pass-gate transistors PG-1, PG-2 provide access to storage nodes SN, SNB during read operations and/or write operations. For example, the pass-gate transistors PG-1, PG-2 couple storage nodes SN, SNB respectively to bit lines BL, BLB in response to voltage applied to the gates of pass-gate transistors PG-1, PG-2 by the word lines WLs.

When the SRAM cell 100 is read from, a positive voltage is placed on the word line WL, and the pass gate transistors PG-1 and PG-2 allow the bit lines BL and BLB to be coupled to, and receive the data from, the storage nodes SN and SNB. Unlike a dynamic memory or DRAM cell, a SRAM cell does not lose its stored state during a read, so no data “write back” operation is required after a read. The bit lines BL and BLB form a complementary pair of data lines. As is known to those skilled in the art, these paired data lines may be coupled to a differential sense amplifier (not shown); and the differential voltage read from SRAM cells can be sensed and amplified. The amplified sensed signal, which is at a logic level voltage, may then be output as read data to other logic circuitry in the device.

In some embodiments, the pull-up transistors PU-1, PU-2 are configured as p-type field-effect transistors (PFETs), and the pull-down transistors PD-1, PD-2 are configured as n-type filed-effect transistors (NFETs). In some implementations, the pass-gate transistors PG-1, PG-2 are also configured as NFETs. Various NFETs and PFETs may be formed by any proper technology, such as fin-like FETs (FinFETs) or gate-all-around (GAA) FETs.

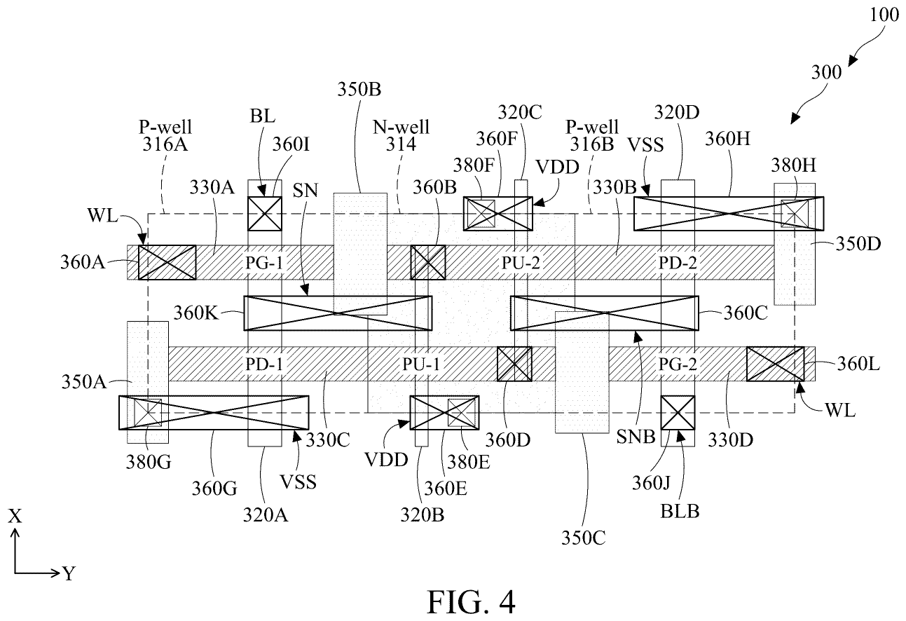

FIG. 4 illustrates a layout 300 of the SRAM cell 100 (represented by the dashed box), of which the circuit diagram is shown in FIG. 3, according to various aspects of the present disclosure. FIG. 4 has been simplified for the sake of clarity to better understand the inventive concepts of the present disclosure. For example, for convenience of illustration, the simplified layout 300 shown in FIG. 4 illustrates, among other features, a layout of wells, active regions, gate structures, source/drain contacts formed on source/drain regions, gate contacts formed on gate structures, and gate isolation features in cut-metal-gate (CMG) trenches that “cut” an otherwise continuous gate structure into multiple segments. Source/drain region(s) may refer to a source or a drain, individually or collectively dependent upon the context. One of ordinary skill in the art should also understand that for the purpose of illustration, FIG. 4 only shows one exemplary configuration of a layout of a 6-T SRAM bit cell. Additional features can be added in the layout 300, and some of the features described below can be replaced, modified, or eliminated corresponding to other embodiments of the SRAM cell 100.

Still referring to FIG. 4, the SRAM cell 100 includes six transistors: a pass-gate transistor PG-1, a pass-gate transistor PG-2, a pull-up transistor PU-1, a pull-up transistor PU-2, a pull-down transistor PD-1, and a pull-down transistor PD-1. The layout 300 thus represents a layout of a 6-T SRAM cell. The SRAM cell 100 includes a region 314 that provides an n-well between a region 316A and a region 316B that each provides a p-well (collectively as region 316). The pull-up transistors PU-1, PU-2 are disposed over the region 314; the pull-down transistor PD-1 and the pass-gate transistor PG-1 are disposed over the region 316A; and the pull-down transistor PD-2 and the pass-gate transistor PG-2 are disposed over the region 316B. In some implementations, the pull-up transistors PU-1, PU-2 are configured as PFETs, and the pull-down transistors PD-1, PD-2 and the pass-gate transistors PG-1, PG-2 are configured as NFETs.

Each of the transistors PG-1, PG-2, PU-1, PU-2, PD-1, and PD-2 includes an active region. In the illustrated embodiment, the SRAM cell 100 includes active regions 320A, 320B, 320C, and 320D (collectively, as the active regions 320) disposed over a semiconductor substrate. The active regions 320 are extending lengthwise in the X-direction and oriented substantially parallel to one another. In the illustrated embodiment, the active regions 320A and 320D have a larger width (measured along the Y-direction) than the active region 320B and 320C, which is to provide stronger current drive to the n-type transistors. Alternatively, the active regions 320 may each have the same width. In some implementations, the active regions 320 are a portion of the semiconductor substrate (such as a portion of a material layer of the semiconductor substrate). For example, where the semiconductor substrate includes silicon, the active regions 320 include fins and project upwardly and continuously from the semiconductor substrate, and the transistors PG-1, PG-2, PU-1, PU-2, PD-1, and PD-2 are FinFET transistors. Alternatively, in some implementations, the active regions 320 are defined in one or more semiconductor material layers, overlying the semiconductor substrate. For example, the active regions 320 can include a stack of nanostructures (nanowires or nanosheets) vertically stacked over the semiconductor substrate, and the transistors PG-1, PG-2, PU-1, PU-2, PD-1, and PD-2 are GAA transistors.

Various gate structures (or referred to as gate stacks, or simply as gates) are disposed over the active regions 320, such as gate structures 330A, 330B, 330C, and 330D (collectively, as the gate structures 330). The gate structures 330 extend lengthwise along the Y-direction (for example, substantially perpendicular to the active regions 320). The gate structures 330 wrap at least portions of the active regions 320, positioned such that the gate structures interpose respective source/drain regions of the active regions 320. The gate structure 330A is disposed over the active region 320A; the gate structure 330C is disposed over the active regions 320A, 320B, 320C; the gate structure 330B is disposed over the active regions 320B, 320C, 320D; and the gate structure 330D is disposed over the active region 320D. A gate of the pass-gate transistor PG-1 is formed from the gate structure 330A, a gate of the pull-down transistor PD-1 is formed from the gate structure 330C, a gate of the pull-up transistor PU-1 is formed from the gate structure 330C, a gate of the pull-up transistor PU-2 is formed from the gate structure 330B, a gate of the pull-down transistor PD-2 is formed from the gate structure 330B, and a gate of the pass-gate transistor PG-2 is formed from the gate structure 330D.

A gate contact 360A electrically connects a gate of the pass-gate transistor PG-1 (formed by gate structure 330A) to a word line WL (generally referred to as a word line node WL), and a gate contact 360L electrically connects a gate of the pass-gate transistor PG-2 (formed by gate structure 330D) to the word line WL. A source/drain contact 360K electrically connects a drain region of the pull-down transistor PD-1 (formed on the active region 320A (which may include n-type epitaxial source/drain features)) and a drain region of the pull-up transistor PU-1 (formed on the active region 320B (which may include p-type epitaxial source/drain features)), such that a common drain of pull-down transistor PD-1 and pull-up transistor PU-1 form a storage node SN. A gate contact 360B electrically connects a gate of the pull-up transistor PU-2 (formed by gate structure 330B) and a gate of the pull-down transistor PD-2 (also formed by gate structure 330B) to the storage node SN. In some embodiments, the gate contact 360B and the source/drain contact 360K are connected as a part of a first butted contact of the SRAM cell 100. A source/drain contact 360C electrically connects a drain region of the pull-down transistor PD-2 (formed on the active region 320D (which may include n-type epitaxial source/drain features)) and a drain region of the pull-up transistor PU-2 (formed on the active region 320C (which may include p-type epitaxial source/drain features)), such that a common drain of pull-down transistor PD-2 and pull-up transistor PU-2 form a storage node SNB. A gate contact 360D electrically connects a gate of the pull-up transistor PU-1 (formed by the gate structure 330C) and a gate of the pull-down transistor PD-1 (also formed by the gate structure 330C) to the storage node SNB. In some embodiments, the gate contact 360D and the source/drain contact 360C are connected as a part of a second butted contact of the SRAM cell 100.

A source/drain contact 360E and a source/drain contact via 380E landing thereon electrically connects a source region of pull-up transistor PU-1 (formed on the active region 320B (which can include p-type epitaxial source/drain features)) to a power supply voltage VDD, and a source/drain contact 360F and a source/drain contact via 380F landing thereon electrically connects a source region of the pull-up transistor PU-2 (formed on the active region 320C (which may include p-type epitaxial source/drain features)) to the power supply voltage VDD. A source/drain contact 360G and a source/drain contact via 380G landing thereon electrically connects a source region of the pull-down transistor PD-1 (formed on the active region 320A (which may include n-type epitaxial source/drain features)) to a grounding voltage VSS, and a source/drain contact 360H and a source/drain contact via 380H electrically connects a source region of the pull-down transistor PD-2 (formed on the active region 320D (which may include n-type epitaxial source/drain features)) to the grounding voltage VSS. The source/drain contact 360G, source/drain contact via 380G, the source/drain contact 360H, and source/drain contact via 380H may be device-level contacts and contact vias that are shared by adjacent SRAM cells 100 (e.g., four SRAM cells 100 abutting at a same corner may share one source/drain contact 360G and one source/drain contact via 380G landing thereon). In the context, a source/drain contact electrically connecting to a source region may also be referred to as a source contact, and a source/drain contact electrically connecting to a drain region may also be referred to as a drain contact.

Bit lines are generally sensitive to parasitic loading. By relocating the source/drain contacts coupled to the bit lines, along with the bit lines themselves, to the backside of the memory device, the distances between these source/drain contacts and adjacent gate structures are increased, reducing parasitic loading and improving circuit performance. In the exemplary layout 300, different from other source/drain contacts, source/drain contacts 360I and 360J are formed on the backside of the SRAM cell 100, which are also referred to as backside source/drain contacts 360I and 360J, respectively. The backside source/drain contact 360I electrically connects a source region of the pass-gate transistor PG-1 (formed on the active region 320A (which may include n-type epitaxial source/drain features)) to a bit line BL, which is also formed on the backside of the SRAM cell 100. The backside source/drain contact 360I is also referred to as backside source contact 360I. The backside source/drain contact 360J electrically connects a source region of the pass-gate transistor PG-2 (formed on the active region 320D (which may include n-type epitaxial source/drain features)) to a complementary bit line BLB, which is also formed on the backside of the SRAM cell 100. The backside source/drain contact 360J is also referred to as backside source contact 360J.

Still referring to FIG. 4, the SRAM cell 100 further includes a plurality of dielectric features extending lengthwise along the X-direction, including dielectric features 350A, 350B, 350C, and 350D (collectively, dielectric features 350 or referred to as isolation features 350). In the illustrated embodiment, the dielectric feature 350B is disposed between the active region 320A and the active region 320B and abuts the gate structure 330A and the gate structure 330B. The dielectric feature 350B divides an otherwise continuous gate structure into two isolated segments corresponding to the gate structure 330A and the gate structure 330B. The dielectric feature 350C is disposed between the active region 320C and the active region 320D and abuts the gate structure 330C and the gate structure 330D. The dielectric feature 350C divides an otherwise continuous gate structure into two isolated segments corresponding to the gate structure 330C and the gate structure 330D. The dielectric feature 350A is disposed near an edge of the SRAM cell 100 and abuts the gate structure 330C. The dielectric feature 350A divides the gate structure 330C from adjoining other gate structure from an adjacent SRAM cell. The dielectric feature 350D is disposed near another edge of the SRAM cell 100 and abuts the gate structure 330B. The dielectric feature 350D divides gate structure 330B from adjoining other gate structure from an adjacent SRAM cell. Each of the dielectric features 350 is formed by filling a corresponding CMG trench in the position of the dielectric features. The dielectric features 350 are also referred to as CMG features.

In the illustrated embodiment, from a top view, the CMG feature 350B is disposed above an interface between the n-well region 314 and the p-well region 316A, the CMG feature 350C is disposed above an interface between the n-well region 314 and the p-well region 316B, the CMG feature 350A is disposed completely above a p-well region that includes the p-well region 316A, and the CMG feature 350D is disposed completely above a p-well region that includes the p-well region 316B.

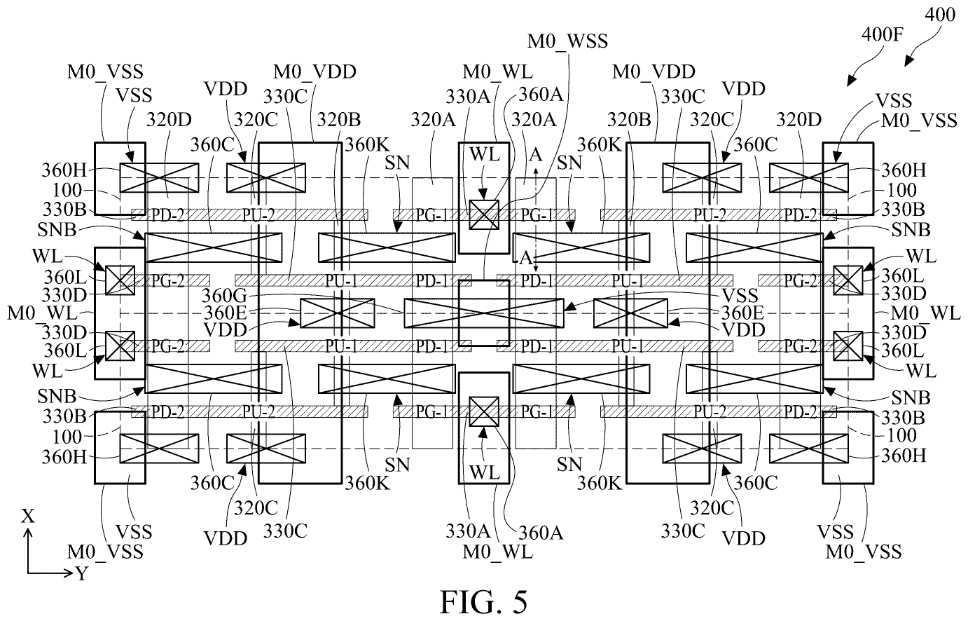

FIG. 5 illustrates a layout 400F of a portion of the device layer DL and the frontside multilayer interconnect structure FMLI of an SRAM array 400 according to the present disclosure. Referring to FIG. 5, four SRAM cells are arranged in the X-direction and the Y-direction, forming a 2×2 array of SRAM cells. Each SRAM cell in the array may use the layout of the SRAM cell 100 as depicted in FIG. 4. In the illustrated embodiment, two adjacent SRAM cells in the X-direction are line symmetric with respect to a common boundary therebetween, and two adjacent SRAM cells in the Y-direction are line symmetric with respect to a common boundary therebetween. FIG. 5 has been simplified for visual clarity and to better illustrate the inventive concepts of the present disclosure. For example, some features depicted in FIG. 4, such as well regions, CMG features, and certain gate vias not intended for pass-gate transistors, are omitted in FIG. 5. Additionally, reference numerals from FIG. 4 are repeated in FIG. 5 for ease of understanding.

For ease of reference, a column is referred to as being in the X-direction of an array, and a row is referred to as being in the Y-direction of an array. As depicted above, adjacent cells in the array are mirror images along a common boundary between the adjacent cells. Some active regions in an SRAM cell may extend through multiple SRAM cells in a column. In FIG. 5, the active region 320A for the transistors PG-1 and PD-1 in one SRAM cell extends into the abutting SRAM cell as the active region for the transistors PD-1 and PG-1 in the abutting SRAM cell. The active region 320B for the transistor PU-1 in one SRAM cell extends into the abutting SRAM cell as the active region for the transistor PU-1 in the abutting SRAM cell. The active region 320D for the transistors PG-2 and PD-2 in one SRAM cell extends into the abutting SRAM cell as the active region for the transistors PD-2 and PG-2 in the abutting SRAM cell. Similarly, some gate structures can be shared by multiple SRAM cells in a row without being interrupted by a CMG feature. For example, the gate structure 330A for the transistor PG-1 in one SRAM cell extends into the abutting SRAM cell as the gate structure for the transistor PG-1 in the abutting SRAM cell. The gate structure 330D for the transistor PG-2 in one SRAM cell extends into the abutting SRAM cell as the gate structure for the transistor PG-2 in the abutting SRAM cell.

The contacts 360 disposed at boundaries of the SRAM cells may also be shared by adjacent SRAM cells. In the illustrated embodiment, the source/drain contact 360G extends into corners regions of four neighboring SRAM cells and is shared by these four SRAM cells. Therefore, the source/drain contact 360G ties the VSS nodes of the four neighboring SRAM cells together. Similarly, the source/drain contact 360H is shared by four respective neighboring SRAM cells. Therefore, the source/drain contact 360H tie the VSS nodes of the four respective neighboring SRAM cells together. The source/drain contact 360E is shared by two respective neighboring SRAM cells. Therefore, the source/drain contact 360E tie the VDD nodes of the two respective neighboring SRAM cells together. Similarly, the source/drain contact 360F is shared by two respective neighboring SRAM cells. Therefore, the source/drain contact 360F tie the VDD nodes of the two respective neighboring SRAM cells together.

FIG. 5 also depicts the M0 metal lines in the frontside multilayer interconnect structure FMLI, including a plurality of VDD lines (denoted as M0_VDD), a plurality of VSS lines (denoted as M0_VSS), and a plurality of WL lines (denoted as M0_WL). Each of the metal lines M0_VDD is a global metal line extending lengthwise in the X-direction through the array and shared by multiple SRAM cells in the same column. Notably, since there are no bit lines or corresponding source/drain contacts coupled to the bit lines on the frontside of the layout 400F, additional space is available for signal routing. For example, each metal line M0_WL may be shared by four gate contacts 360L or four gate contacts 360A from four neighboring SRAM cells without being segmented by signal routing for bit lines.

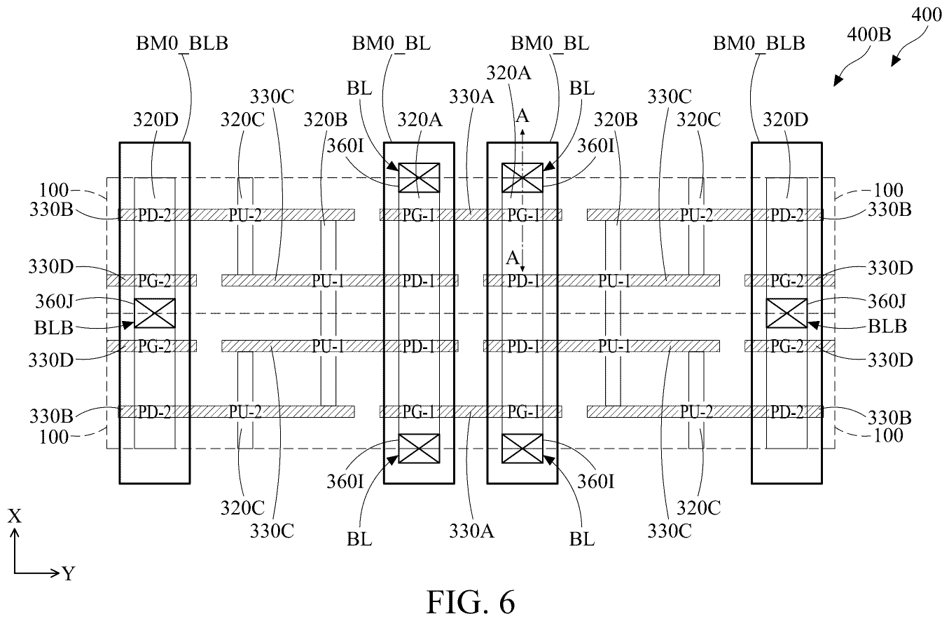

Reference is now made to FIG. 6. FIG. 6 illustrates a layout 400B of a portion of the backside multilayer interconnect structure BMLI of the SRAM array 400, which includes a backside via zero level (BV0 level) and a backside metal zero level (BM0 level). For reasons of visual clarity and to better understand the inventive concepts of the present disclosure, active regions and gate structures as depicted in FIG. 5, which are at the frontside of the SRAM array 400, are overlaying on the layout 400B to aid visual clarity.

The BV0 level includes backside source/drain contacts (or referred to as backside vias) 360I and 360J. The BM0 level includes backside bit line BM0_BL and backside complementary bit line BM0_BLB, which are collectively referred to as backside bit lines. Similar to functions of the frontside source/drain contacts, the backside source/drain contacts 360I and 360J electrically couple the source regions of the pass-gate transistors PG-1 and PG-2 to the backside bit lines BM0_BL and BM0_BLB, respectively. The backside source/drain contacts 360I and 360J may have the same dimension along the Y-direction as the active regions 320A and 320D, respectively. This is due to one exemplary backside manufacturing flow in which the backside vias is formed by etching a fin-shape base in an active region from the backside to form a backside trench and filling the backside trench with conductive materials. Therefore, the backside vias inherit the width of the active region.

Each of the backside bit lines BM0_BL and BM0_BLB is a global metal line extending lengthwise in the X-direction through the array and shared by multiple SRAM cells in the same column. Since there is no word line or power line routing on the backside, the backside bit lines BM0_BL and BM0_BLB may occupy a larger width (measured in the Y-direction) than certain metal lines on the frontside (e.g., M0_WL and M0_VSS) to achieve lower routing resistance. In the depicted embodiment in FIG. 6, each of the backside bit lines BM0_BL and BM0_BLB in the Y-direction does not extend beyond the boundary of an SRAM cell 100, and the width of the bit lines BM0_BL and BM0_BLB may be still smaller than the VDD lines M0_VDD.

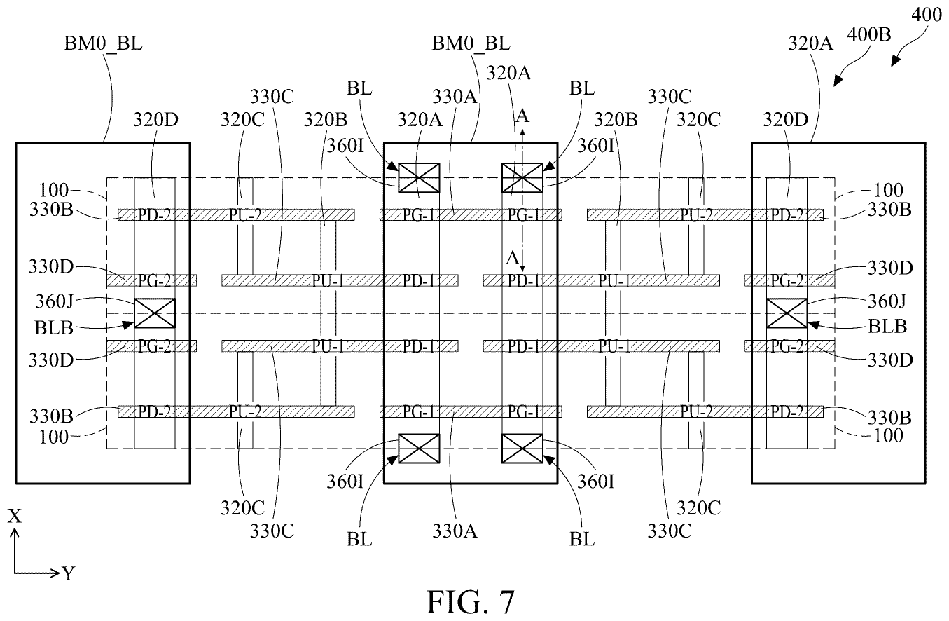

Alternatively, two adjacent SRAM cells 100 along the Y-direction may share one wider backside bit line. FIG. 7 illustrates such an alternative layout 400B′ of a portion of the backside multilayer interconnect structure BMLI of the SRAM array 400. In the depicted embodiment in FIG. 7, each of the backside bit lines BM0_BL and BM0_BLB in the Y-direction extends beyond the boundary of an SRAM cell 100 and coupled to two backside source/drain contacts 360I or 360J in the same row. The width of the bit lines BM0_BL and BM0_BLB may be larger than the VDD lines M0_VDD and other metal lines on the frontside (e.g., M0_WL and M0_VSS).

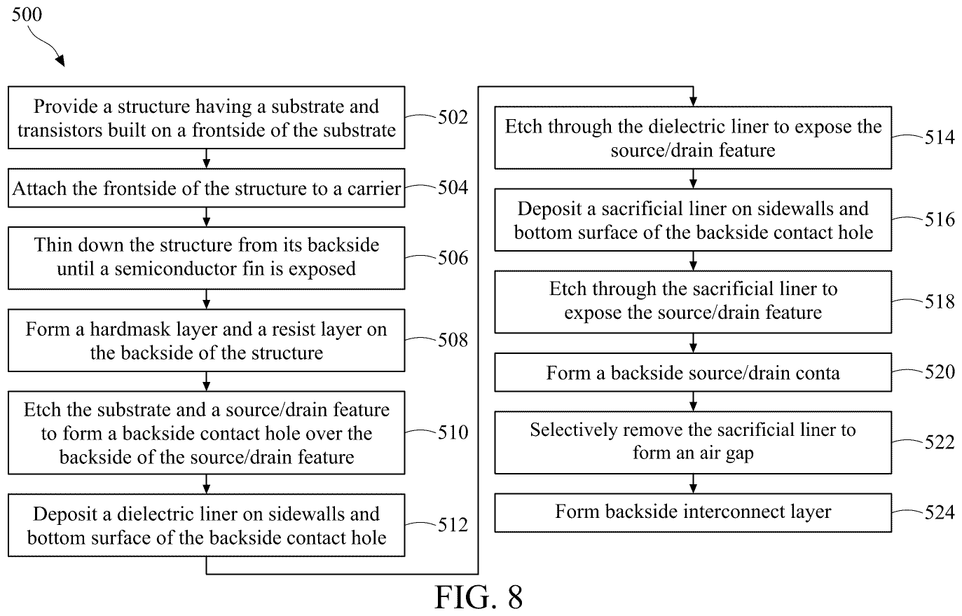

FIG. 8 illustrates a flow chart of a method 500 for fabricating a semiconductor device (or device) 600 that is substantially similar to or as a portion of the SRAM array 400 as depicted in FIGS. 5-7 according to various embodiments of the present disclosure. Additional processing is contemplated by the present disclosure. Additional operations can be provided before, during, and after method 500, and some of the operations described can be moved, replaced, or eliminated for additional embodiments of method 500.

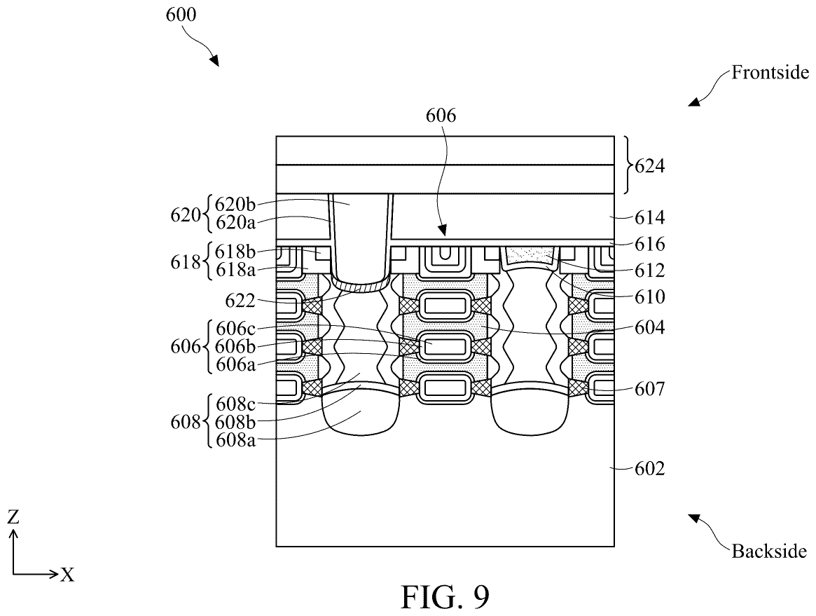

The method 500 is described below in conjunction with FIG. 9 through FIG. 24 that illustrate cross-sectional views of the semiconductor device 600 at various steps of fabrication according to the method 500, in accordance with some embodiments. The cross-sectional views of the device 600 in FIG. 9 through FIG. 24 are along the A-A line in FIGS. 5-7 and illustrate, among other features, a frontside source/drain contact corresponding to the source/drain contact 360K (or a butted contact) of the storage node SN, and a backside source/drain contact corresponding to the backside source/drain contact 360I coupled to a backside bit line BM0_BL. FIG. 9 through FIG. 24 have been simplified for the sake of clarity to better understand the inventive concepts of the present disclosure. Additional features can be added in the device 600, and some of the features described below can be replaced, modified, or eliminated in other embodiments of the device 600.

At operation 502, the method 500 (FIG. 8) provides the device 600 having a substrate 602 at its backside and various elements including transistors built on its frontside, such as shown in FIG. 9. These elements include channel layers 604 vertically stacked above the substrate 602, a pair of source/drain features 608 connected by the channel layers 604, a gate structure 606 wrapping around each of the channel layers 604, inner spacers 607 interposing between the gate structure 606 and the source/drain features 608, and gate spacers 618 disposed on sidewalls of the gate structure 606. The channel layers 604 and the source/drain features 608 correspond to the channel regions and source/drain regions of the active region 320A (FIGS. 5-7), respectively. The gate structure 606 engages the channel layer 604, defining a transistor corresponding to the pull-up transistor PG-1 (FIGS. 5-7).

The device 600 further includes a contact etch stop layer (CESL) 610 over the source/drain features 608, a first inter-layer dielectric (ILD) layer 612 over the CESL 610, and a second ILD layer 614 over the first ILD layer 612, a frontside source/drain contact 620 (corresponding to the source/drain contact 360K in FIG. 5) disposed on one of the source/drain features 608, and a silicide feature 622 interposed between the frontside source/drain contact 620 and respective source/drain feature 608. The first and second ILD layers may be separated by an etch stop layer (ESL) 616.

The device 600 further includes one or more interconnect layers with wires and vias embedded in dielectric layers. The one or more interconnect layers connecting gate, source, and drain electrodes of various transistors, as well as other circuits in the device 600, to form an integrated circuit in part or in whole. The device 600 may further include passivation layers, adhesion layers, and/or other layers built on the frontside of the device 600. These layers and the one or more interconnect layers are collectively denoted with the label 624.

In some embodiments, the substrate 602 is a bulk silicon substrate (i.e., including bulk single-crystalline silicon). The substrate 602 may include other semiconductor materials in various embodiment, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof. In an alternative embodiment, the substrate 602 is a semiconductor-on-insulator substrate, such as a silicon-on-insulator (SOI) substrate, a silicon germanium-on-insulator (SGOI) substrate, or a germanium-on-insulator (GOI) substrate.

In some embodiments, the channel layers 604 include a semiconductor material suitable for transistor channels, such as silicon (Si), or other semiconductor material(s). The channel layers may be in the shape of rods, bars, sheets, or other shapes in various embodiments. In an embodiment, the channel layers 604 are initially part of a stack of semiconductor layers that include the channel layers 604 and other sacrificial semiconductor layers alternately stacked layer-by-layer. The sacrificial semiconductor layers and the channel layers 604 include different material compositions (such as different semiconductor materials, different constituent atomic percentages, and/or different constituent weight percentages) to achieve etching selectivity. During a gate replacement process to form the gate structure 606, the sacrificial semiconductor layers are selectively removed, leaving the channel layers 604 suspended over the substrate 602.

In some embodiments, the source/drain features 608 include epitaxially grown one or more layers of semiconductor materials such as epitaxially grown silicon, germanium, or silicon germanium. In the depicted embodiment, the source/drain features 608 includes a buffer epitaxial layer 608a, an intermediate layer 608b, and a doped epitaxial layer 608c. By way of example, epitaxial growth of the buffer epitaxial layer 608a may be performed by vapor-phase epitaxy (VPE), ultra-high vacuum chemical vapor deposition (UHV-CVD), molecular beam epitaxy (MBE), and/or other suitable processes. In some embodiments, the buffer epitaxial layer 608a include the same material as the substrate 602, such as silicon (Si). In some alternative embodiments, the buffer epitaxial layer 608a includes a different semiconductor material than the substrate 602, such as silicon germanium (SiGe). In some embodiments, the buffer epitaxial layer 608a is dopant-free, where for example, no intentional doping is performed during the epitaxial growth process. Alternatively, the buffer epitaxial layer 608a may be slightly doped with dopants such as Ge or Sn. As a comparison, in one instance, the substrate 602 is lightly doped and has a higher doping concentration than the buffer epitaxial layer 608a. The buffer epitaxial layer 608a provides a high resistance path from the upper portions of the source/drain features to the semiconductor substrate, such that the leakage current through the semiconductor substrate is suppressed.

The intermediate layer 608b may be conformally deposited over the device 600. In various examples, the intermediate layer 608b is a nitride layer blanket deposited by a chemical vapor deposition (CVD) process, a subatmospheric CVD (SACVD) process, a flowable CVD process, an atomic layer deposition (ALD) process, a physical vapor deposition (PVD) process, and/or other suitable process. The intermediate layer 608b may be also referred to as a blanket nitride layer. In some embodiments, the blanket nitride layer 608b includes silicon nitride (SiN). Subsequently, the doped epitaxial layer 608c is formed on the blanket nitride layer 608b. After the forming of the doped epitaxial layer 608c, an etching process is performed to remove portions of the blanket nitride layer 608b not stacked between the epitaxial layers 608a and 608c. The blanket nitride layer 608b functions as an etch stop layer in subsequent backside etching process. By way of example, the doped epitaxial layer 608c may be formed by any epitaxy processes including VPE, UHV-CVD, MBE, and/or other suitable processes. The doped epitaxial layer 608c may be doped with n-type dopants and/or p-type dopants. In some embodiments, for n-type transistors, the doped epitaxial layer 608c include silicon and can be doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for p-type transistors, the doped epitaxial layer 608c include silicon germanium or germanium, and can be doped with boron, other p-type dopant, or combinations thereof (for example, forming Si:Ge:B epitaxial source/drain features). In one embodiment, the doped epitaxial layer 608c and the buffer epitaxial layer 608a are both formed of silicon (Si). In another embodiment, the doped epitaxial layer 608c is formed of silicon (Si) and the buffer epitaxial layer 608a is formed silicon germanium (SiGe). The doped epitaxial layer 608c may further include multiple epitaxial semiconductor layers having different levels of dopant density. In some embodiments, annealing processes (e.g., rapid thermal annealing (RTA) and/or laser annealing) are performed to activate dopants in the doped epitaxial layer 608c.

In some embodiment, the gate structure 606 includes an interfacial layer 606a, a high-k dielectric layer 606b, and a gate electrode layer 606c. The interfacial layer 606a and the high-k dielectric layer 606b may be collectively referred to as a gate dielectric layer. The gate dielectric layer may be formed by chemical oxidation, thermal oxidation, ALD, CVD, and/or other suitable methods. The interfacial layer 606a may include silicon dioxide, silicon oxynitride, or other suitable materials. The high-k dielectric layer 606b may include a high-k dielectric material such as HfO₂, or other suitable high-k dielectric material. The high-k dielectric material generally refers to dielectric materials having a high dielectric constant, for example, greater than that of silicon oxide (k≈3.9). The gate electrode layer 606c may include an n-type or a p-type work function layer and a metal fill layer. For example, an n-type work function layer may comprise a metal with sufficiently low effective work function such as titanium, aluminum, tantalum carbide, tantalum carbide nitride, tantalum silicon nitride, or combinations thereof. For example, a p-type work function layer may comprise a metal with a sufficiently large effective work function, such as titanium nitride, tantalum nitride, ruthenium, molybdenum, tungsten, platinum, or combinations thereof. For example, a metal fill layer may include aluminum, tungsten, cobalt, copper, and/or other suitable materials. The gate electrode layer 606c may be formed by CVD, PVD, plating, and/or other suitable processes. Since the gate structure 606 includes a high-k dielectric layer and metal layer(s), it is also referred to as a high-k metal gate (HKMG).

In some embodiments, the gate spacers 618 include a dielectric material such as a dielectric material including silicon, oxygen, carbon, nitrogen, other suitable material, or combinations thereof (e.g., silicon oxide, silicon nitride, silicon oxynitride (SiON), silicon carbide, silicon carbon nitride (SiCN), silicon oxycarbide (SiOC), silicon oxycarbon nitride (SiOCN)). In some embodiments, the gate spacers 618 include a multi-layer structure, such as a first dielectric layer 618a that includes silicon nitride and a second dielectric layer 618b that includes silicon oxide.

In some embodiments, the inner spacers 607 include silicon carbonitride (SiCN), silicon oxycarbonitride (SiOCN), silicon nitride (SiN), silicon oxycarbide (SiOC), or silicon oxynitride (SiON). A material composition of the inner spacers 607 may be the same or different from the gate spacers 618. The inner spacers 607 may be deposited using CVD or ALD. The inner spacers 607 interpose between the gate structure 606 and the source/drain features 608 and electrically isolate the gate structure 606 from the source/drain features 608.

In some embodiments, the CESL 610 includes La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The first ILD layer 612 and the second ILD layer 614 may comprise tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The first ILD layer 612 and/or the second ILD layer 614 may be formed by PE-CVD (plasma enhanced CVD), F-CVD (flowable CVD), or other suitable methods.

In some embodiments, the silicide features 622 includes titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

In some embodiments, the frontside source/drain contact 620 includes a conductive barrier layer 620a and a metal fill layer 620b over the conductive barrier layer 620a. The conductive barrier layer 620a may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The metal fill layer 620b may include tungsten (W), cobalt (Co), molybdenum (Mo), ruthenium (Ru), nickel (Ni), copper (Cu), or other metals, and may be formed by CVD, PVD, ALD, plating, or other suitable processes. In the illustrated embodiment, the metal fill layer 620b is in physical contact with the conductive barrier layer 620a, and the conductive barrier layer 620a is in physical contact with the second ILD layer 614. In some embodiments, the conductive barrier layer 620a is omitted in the source/drain contact 620, such that the metal fill layer 620b may be in physical contact with the second ILD layer 614. The source/drain feature 608 with the frontside source/drain contact 620 landing on may have a concave top surface with a center point of the concave profile below a top surface of the topmost one of the channel layers 604. As a comparison, the other one of the source/drain features 608 in the pair may have a convex top surface with a center point of the convex profile above the top surface of the topmost one of the channel layers 604. In the depicted embodiment, it is a drain feature that the frontside source/drain contact 620 lands on, and thus the frontside source/drain contact 620 is also referred to as the frontside drain contact 620. As a comparison, the other source/drain feature in the pair is a source feature, and the subsequently formed backside source/drain contact landing on its bottom surface is also referred to as the backside source contact.

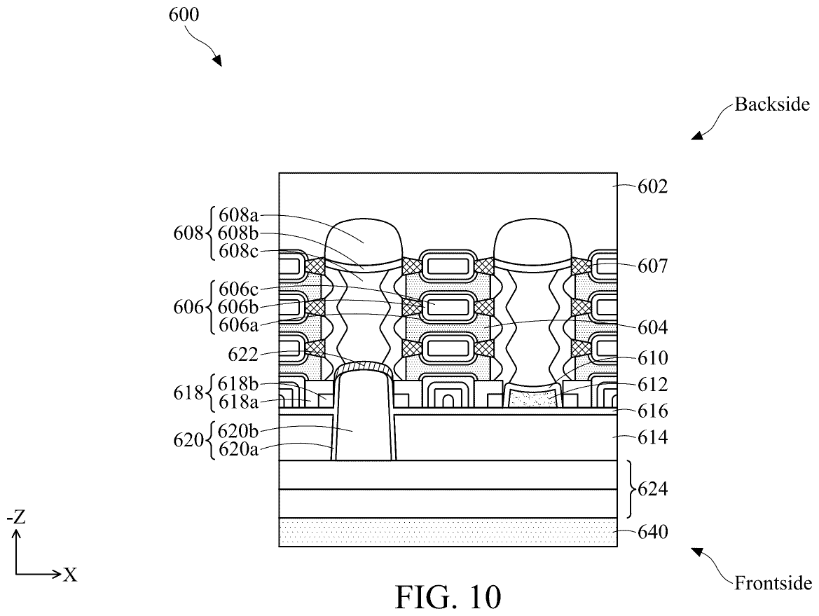

At operation 504, the method 500 (FIG. 8) flips the device 600 upside down and attaches the frontside of the device 600 to a carrier 640, such as shown in FIG. 10. This makes the device 600 accessible from the backside of the device 600 for further processing. The operation 504 may use any suitable attaching processes, such as direct bonding, hybrid bonding, using adhesive, or other bonding methods. The operation 504 may further include alignment, annealing, and/or other processes. The carrier 640 may be a silicon wafer in some embodiments. In FIGS. 10-24, the “Z” direction points from the backside of the device 600 to the frontside of the device 600, while the “−Z” direction points from the frontside of the device 600 to the backside of the device 600.

Still referring to FIG. 10, at operation 506, the method 500 (FIG. 8) thins down the device 600 from the backside of the device 600. The thinning process may include a mechanical grinding process and/or a chemical thinning process. A substantial amount of substrate material may be first removed from the substrate 602 during a mechanical grinding process. Afterwards, a chemical thinning process may apply an etching chemical to the backside of the substrate 602 to further thin down the substrate 602.

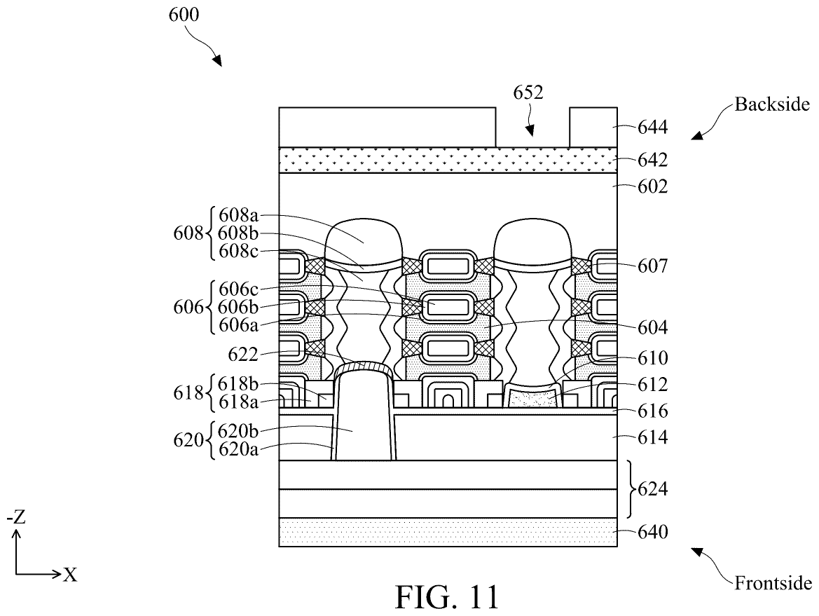

At operation 508, the method 500 (FIG. 8) forms a hard mask layer 642 over the backside of the device 600 and a resist layer 644 over the hard mask layer 642, such as shown in FIG. 11. The hard mask layer 642 may include an oxide (e.g., SiO₂), a nitride (e.g., SiN), an oxy-nitride (e.g., SiO_{X}N_{Y}), or the like. In further embodiments, the hard mask layer 642 is made of SiO₂. In yet further embodiments, the hard mask layer 642 is a high-temperature oxide (HTO) (e.g., SiO₂ formed by a high-temperature deposition/growth process). In some embodiments, a process for forming the hard mask layer 642 comprises depositing a dielectric material on the backside of the device 600 by, for example, CVD, PVD, ALD, sputtering, some other deposition process, or a combination thereof.

The resist layer 644 may be a tri-layer resist layer that includes a bottom layer over the hard mask layer 642, a middle layer over the bottom layer, and an upper layer over the middle layer. The bottom layer may be a bottom anti-reflective coating (BARC). The bottom layer may include organic materials. The middle layer may be formed from or include an inorganic material, which may be a nitride (such as silicon nitride), an oxynitride (such as silicon oxynitride), an oxide (such as silicon oxide), or the like. The upper layer is a photosensitive material. The middle layer has a high etching selectivity relative to the upper layer and the bottom layer. As a result, the upper layer is used as an etching mask for the patterning of the middle layer, and the middle layer is used as an etching mask for the patterning of the bottom layer. In some embodiments, the resist layer formed over the hard mask layer 642 may be another type of photoresist, such as a single-layer photoresist, a bi-layer photoresist, or the like. The resist layer 644 is patterned using any suitable photolithography technique to form a backside opening 652 therein.

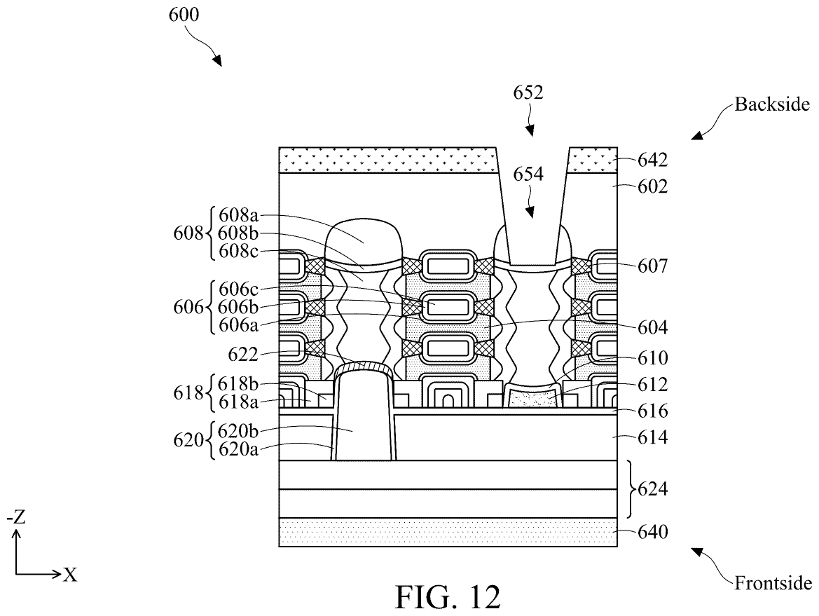

At operation 510, the method 500 (FIG. 8) extends the backside opening 652 to the hard mask layer 642 and selectively etches through the substrate 602 and the buffer epitaxial layer 608a to form a backside contact hole 654, as shown in FIG. 12. During the patterning of the hard mask layer 642, the resist layer 644 may be consumed. In some embodiments, an ashing process may be performed to remove the resist layer 644. After the hard mask layer 642 exposes the backside of the device 600, the operation 510 applies an etching process that is tuned to be selective to the materials of the semiconductor material (e.g. silicon) in the substrate 602. In the present embodiment, the etching process also etches the buffer epitaxial layer 608a of the source/drain feature 608. The blanket nitride layer 608b of the source/drain feature 608 functions as an etch stop layer to protect the doped epitaxial layer 608c from being etched. The etching of the substrate 602 and the buffer epitaxial layer 608a may include a first etching to selectively etch through the substrate 602 and a second etching to selective etch through the buffer epitaxial layer 608a. The etching process(es) can be dry etching, wet etching, reactive ion etching, or other suitable etching methods.

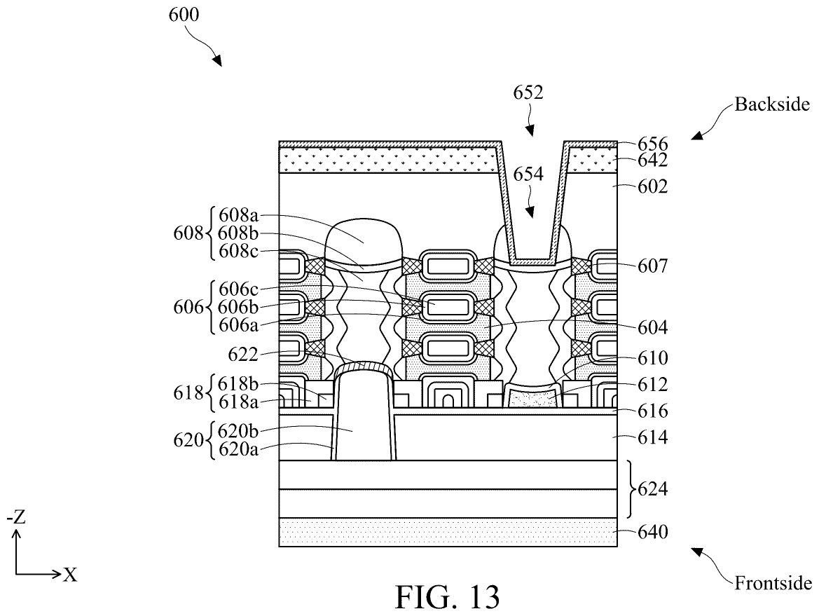

At operation 512, the method 500 (FIG. 8) deposits a dielectric liner 656 on sidewalls and bottom surface of the backside contact hole 654 (including on backside surface of the device 600), such as shown in FIG. 13. The dielectric liner 656 further protects the gate structure 606 from metal element diffusion when conductive features are subsequently formed in the backside contact hole 654. In the illustrated embodiment, the dielectric liner 656 is conformally deposited to have a substantially uniform thickness along the various surfaces of the backside of the device 600. In various embodiments, the dielectric liner 656 may include SiN, SiOCN, SiOC, SiCN, SiO₂, SiC, ZnO, ZrN, Zr₂Al₃O₉, TiO₂, TaO₂, ZrO₂, HfO₂, Y₂O₃, La₂O₃, Al₂O₃, AlON, TaCN, ZrSi, combinations thereof, or other suitable material(s). The dielectric liner 656 may be deposited using ALD, CVD, or other suitable methods.

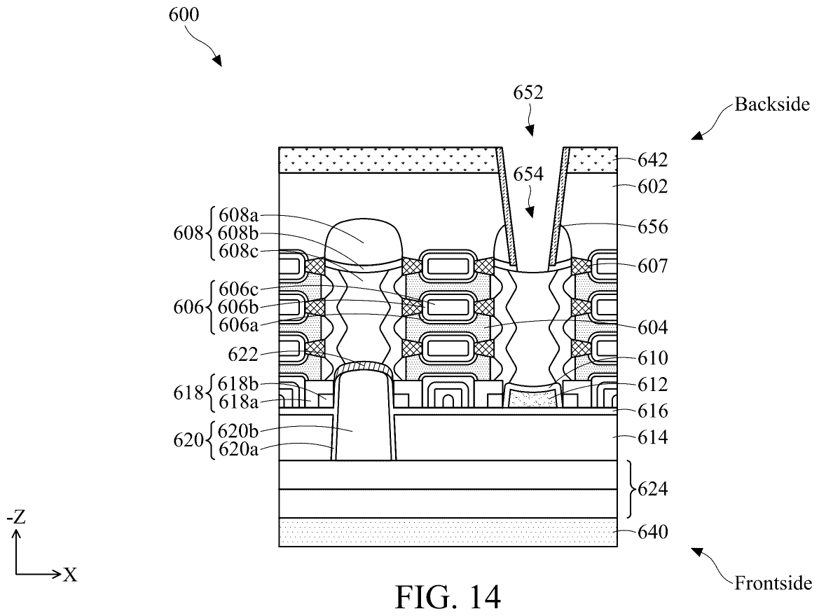

At operation 514, the method 500 (FIG. 8) performs an etching process for breaking through, and removing the majority of, the horizontal portions of the dielectric liner 656, such as shown in FIG. 14. The etching process is also referred to as a breakthrough (BT) etching process. In some embodiments, the BT etching process may include an anisotropic dry etch process, or the like. In some embodiments where the dielectric liner 656 is formed of a nitride (e.g., silicon nitride), the BT etch process is a reactive ion etch (RIE) process with etch process gases including CHF₃, Ar, CF₄, N₂, O₂, CH₂F₂, SF₃, the like, or a combination thereof. The RIE process may be performed for an etch time between about 2 seconds and about 20 seconds, at a pressure between about 2 mTorr and about 30 mTorr, a temperature between about 10° C. and about 100° C., a radio frequency (RF) power between about 100 W and about 1500 W, and a voltage bias between about 10 V and about 800 V. In the illustrated embodiment, as a result of the operation 514, portions of the dielectric liner 656 remain on sidewalls of the backside contact hole 654. The dielectric liner 656 may also be in contact with the buffer epitaxial layer 608a and the blanket nitride layer 608b in the depicted embodiment. After the BT etching process, the blanket nitride layer 608b as an etch stop layer is exposed in the backside contact hole 654. Subsequently, an etching process is applied to remove the exposed portion of the blanket nitride layer 608b. The etching process(es) can be dry etching, wet etching, reactive ion etching, or other etching methods. At the conclusion of operation 514, the backside contact hole 654 exposes the bottom surface of the doped epitaxial layer 608c of the source/drain feature 260 from the backside. A portion of the blanket nitride layer 608b remains between the doped epitaxial layer 608c and the dielectric liner 656. The bottom surface of the doped epitaxial layer 608c may have a concave profile bending towards the frontside of the device 600.

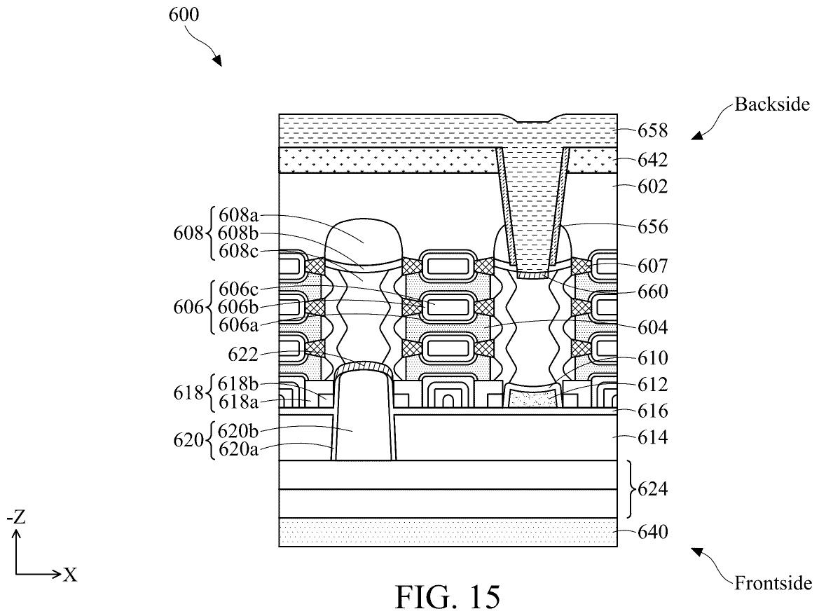

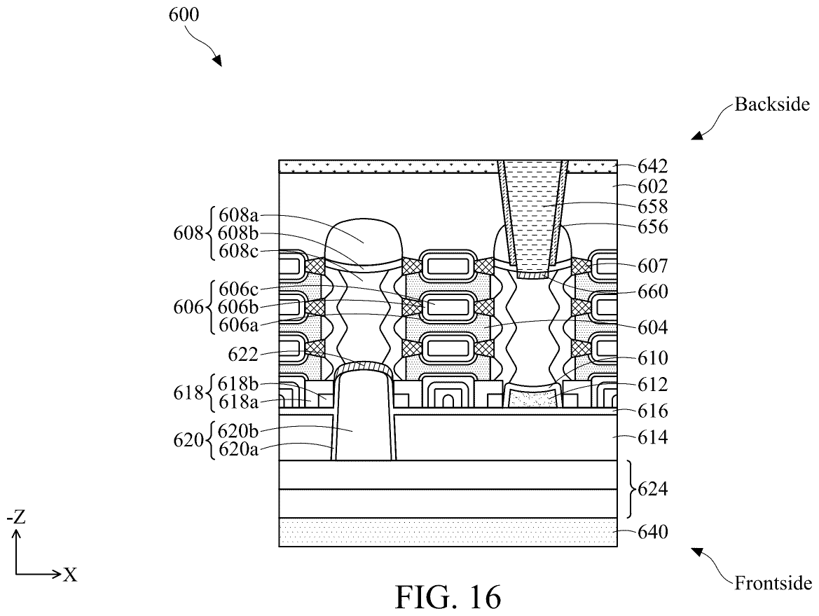

In some embodiments, after operations 514, the method 500 (FIG. 8) may proceed directly to operation 520 and skip operations 516 and 518, which will be discussed in further detail below. At operation 520, the method 500 (FIG. 8) forms a backside source/drain contact 658 in the backside contact hole 654, as shown in FIGS. 15 and 16. In some embodiments, the backside source/drain contact 658 is formed by filling the backside contact hole 654 with one or more conductive materials, such as shown in FIG. 15, and subsequently removing excessive conductive materials from the backside of the device 600 in a planarization process, such as shown in FIG. 16. The backside source/drain contact 658 may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be formed by CVD, PVD, ALD, plating, or other suitable processes. In the illustrated embodiment, operation 516 forms a backside silicide feature 660 on the bottom surface of the doped epitaxial layer 608c of the source/drain feature 608. The backside silicide feature 660 reduces contact resistance between the source/drain feature 608 and the backside source/drain contact 658. In furtherance of the embodiment, operation 516 first deposits one or more metals into the backside contact hole 654, performing an annealing process to the device 600 to cause reaction between the one or more metals and the source/drain features 608 to produce the silicide feature, and removing un-reacted portions of the one or more metals, leaving the silicide feature in the backside contact hole 654. The one or more metals may include titanium (Ti), tantalum (Ta), tungsten (W), nickel (Ni), platinum (Pt), ytterbium (Yb), iridium (Ir), erbium (Er), cobalt (Co), or a combination thereof (e.g., an alloy of two or more metals) and may be deposited using CVD, PVD, ALD, or other suitable methods. The backside silicide feature 660 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), a combination thereof, or other suitable compounds. The backside source/drain contact 658 and the backside silicide feature 660 may collectively be referred to as the backside source/drain contact. Alternatively, the formation of the backside silicide feature 660 may be omitted, and the backside source/drain contact 658 may be in physical contact with the source/drain feature 608. A planarization operation, such as a chemical mechanical polishing (CMP) process, may also be performed to remove excessive conductive material and expose the backside of the hard mask layer 642, such as shown in FIG. 16.

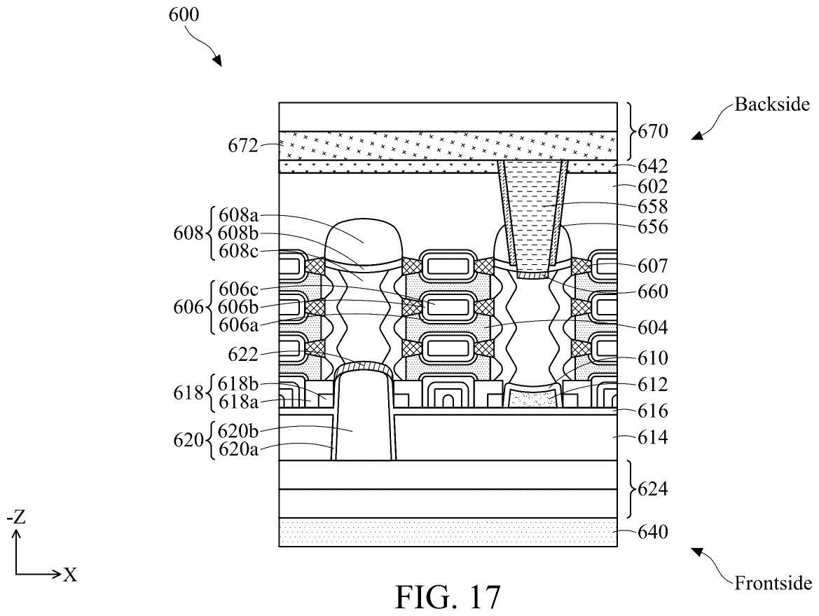

In some embodiments, after operations 520, the method 500 (FIG. 8) may proceed directly to operation 524 and skip operation 522, which will be discussed in further detail below. At operation 524, the method 500 (FIG. 8) forms one or more backside interconnect layers 670 with backside metal lines embedded in dielectric layers on the backside of the device 600, such as shown in FIG. 17. In the illustrated embodiment, the backside metal lines include a backside bit line 672 in a backside M0 interconnect layer) that lands on the backside source/drain contact 658 and electrically couples the respective source/drain feature 608. The backside bit line 672 corresponds to the backside bit line BM0_BL in FIG. 6 or FIG. 7. The backside bit line 672 may include a conductive barrier layer and a metal fill layer over the conductive barrier layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The metal fill layer may include tungsten (W), cobalt (Co), molybdenum (Mo), ruthenium (Ru), nickel (Ni), copper (Cu), or other metals, and may be formed by CVD, PVD, ALD, plating, or other suitable processes. In some embodiments, the conductive barrier layer is omitted. In an embodiment, the backside metal lines may be formed using a damascene process, a dual-damascene process, a metal patterning process, or other suitable processes. Although not shown in FIG. 17, the backside interconnect layers 670 may include other backside contacts, vias, wires, and/or other conductive features. Having the bit lines relocated to the backside of the device 600 enlarges the distance between the backside source/drain contact 658 and the gate structure 606 and reduces parasitic capacitance loaded to the bit lines. Besides, as discussed above, the backside bit lines may have wider dimension than the first level metal (M0) tracks on the frontside of the device 600, which beneficially reduces the backside routing resistance.

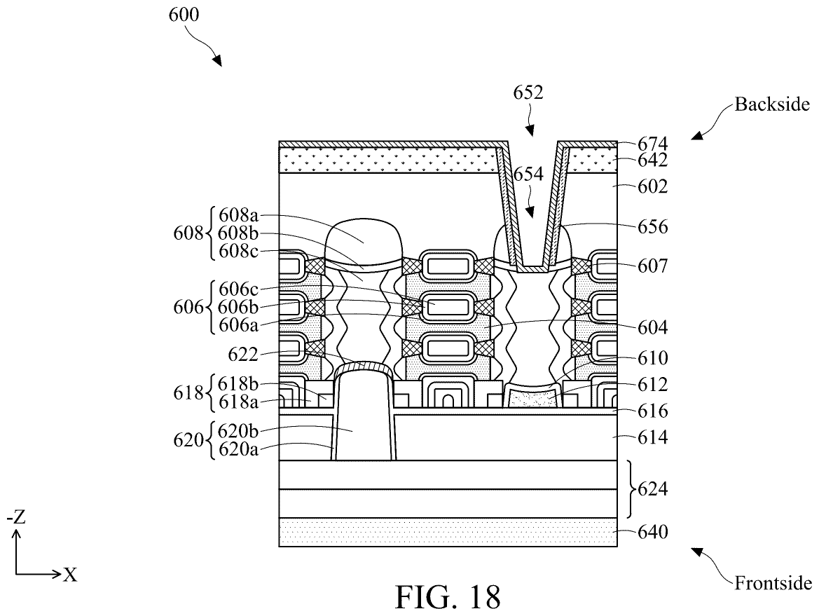

In some alternative embodiments, after operation 514, the method 500 (FIG. 8) may proceed to operations 516 and 518 before performing operation 520. At operation 516, the method 500 (FIG. 8) forms a sacrificial liner 674 on sidewalls and bottom surface of the backside contact hole 654 (including on backside surface of the device 600), such as shown in FIG. 18. The sacrificial liner 674 includes a different material composition from the dielectric liner 656, which allows the sacrificial liner 674 to be later removed by a selective etching process. In one example, the dielectric liner 656 includes a nitride (e.g., silicon nitride), and the sacrificial liner 674 includes an oxide (e.g., silicon oxide). In another example, the dielectric liner 656 includes an oxide (e.g., silicon oxide), and the sacrificial liner 674 includes a nitride (e.g., silicon nitride). In yet another example, the dielectric liner 656 includes a dielectric material, and the sacrificial liner 674 includes a semiconductor material, such as silicon (Si). In furtherance of the example, the sacrificial liner 674 may include amorphous silicon. In the illustrated embodiment, the sacrificial liner 674 is conformally deposited to have a substantially uniform thickness along the various surfaces of the backside of the device 600. A thickness of the sacrificial liner 674 may be larger than a thickness of the dielectric liner 656. The larger thickness of the sacrificial liner 674 allows later forming an air gap with a meaningful volume after the selective removal of the sacrificial liner 674 to further effectively reduce parasitic capacitance loaded to the bit lines. A ratio of the thickness of the sacrificial liner 674 to the thickness of the dielectric liner may range from about 1.2 to 3. The sacrificial liner 674 may be deposited using ALD, CVD, or other suitable methods.

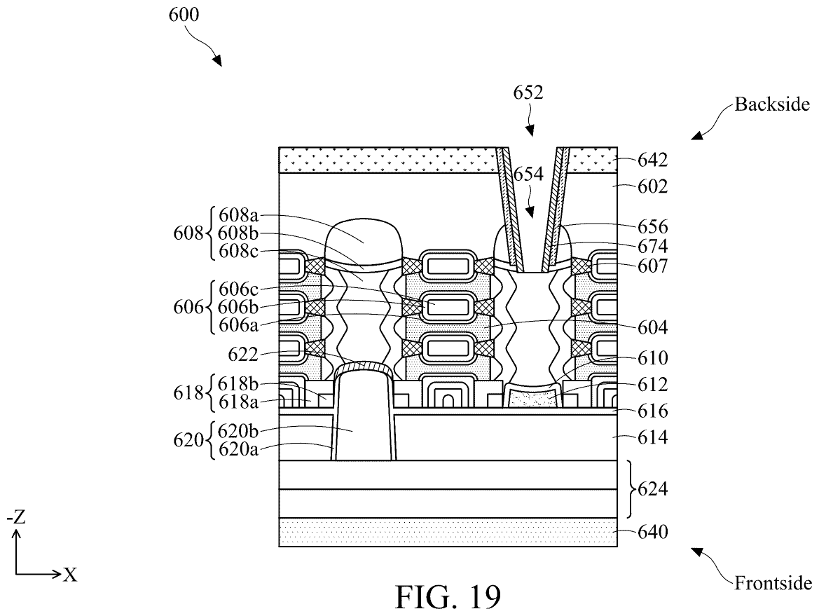

At operation 518, the method 500 (FIG. 8) performs an etching process for breaking through, and removing the majority of, the horizontal portions of the sacrificial liner 674, such as shown in FIG. 19. The etching process is also referred to as a breakthrough (BT) etching process. In some embodiments, the BT etching process may include an anisotropic dry etch process, or the like. In the illustrated embodiment, as a result of the operation 518, portions of the sacrificial liner 574 remain on sidewalls of the backside contact hole 654, and the doped epitaxial layer 608c of the source/drain feature 260 is exposed again. The sacrificial liner 674 may cover ends of the blanket nitride layer 608b from being exposed, in the depicted embodiment.

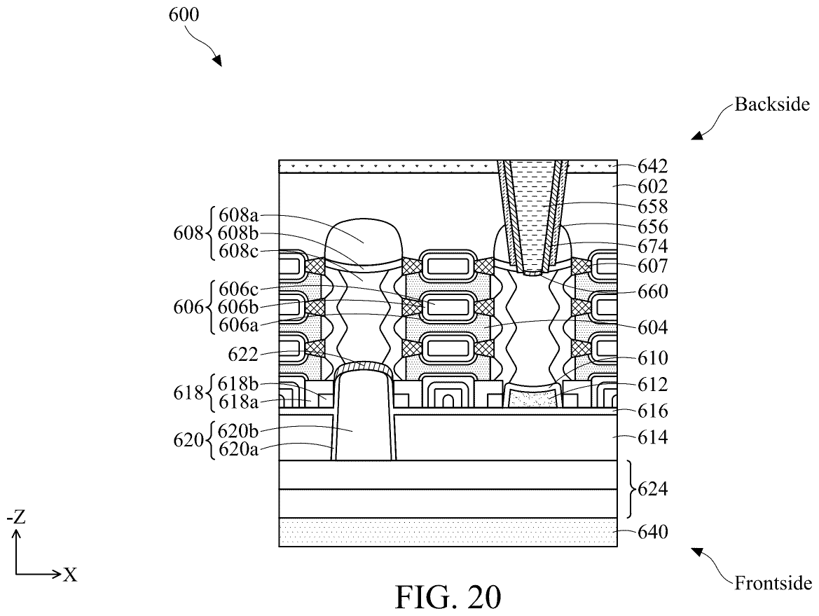

At operation 520, the method 500 (FIG. 8) forms the backside silicide feature 660 and the backside source/drain contact 658 in the backside contact hole 654, as shown in FIG. 20. A planarization operation, such as a chemical mechanical polishing (CMP) process, may also be performed to remove excessive conductive material and expose the backside of the hard mask layer 642. The sacrificial liner 674 separates the backside silicide feature 660 and the backside source/drain contact 658 from contacting the dielectric liner 656 and the blanket nitride layer 608b. In some embodiments, the formation of the backside silicide feature 660 may be omitted, and the backside source/drain contact 658 may be in physical contact with the source/drain feature 608.

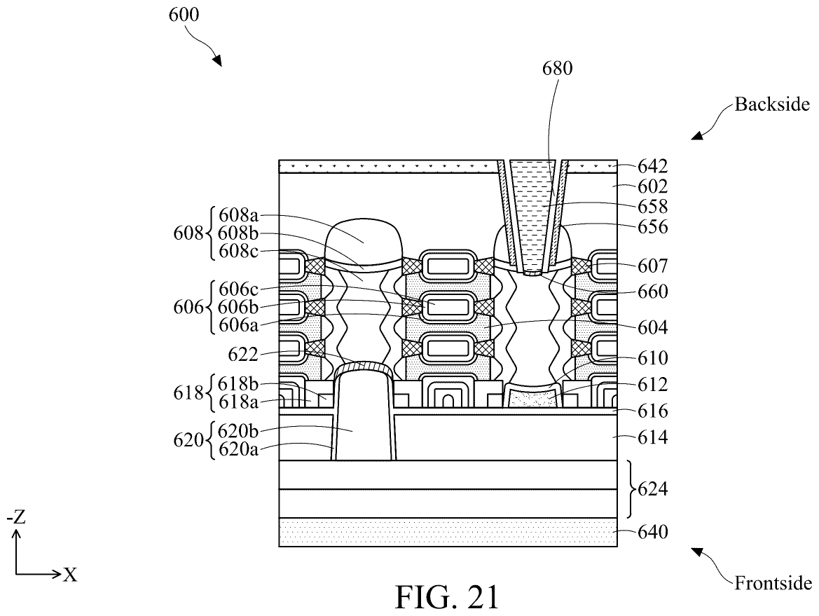

At operation 522, the method 500 (FIG. 8) selectively removes the sacrificial liner 674 from the backside of the device 600 to form a gap 680, such as shown in FIG. 21. An etching process is performed to selectively remove the sacrificial liner 674 without substantially etching the dielectric liner 656 or other components of the device 600. The gap 680 tracks the shape of the sacrificial liner 674. For example, a width of the gap 680 may be larger than a thickness of the dielectric liner 656. A ratio of the width of the gap 680 to the thickness of the dielectric liner may range from about 1.2 to 3, in some embodiments. The gap 680 is also referred to as the air gap 680. As used herein, the term “gap” or “air gap” is used to describe a void defined by surrounding substantive features, where a void may contain air, nitrogen, ambient gases, gaseous chemicals used in fabrication processes, or combinations thereof. The etching process may include a dry etching process, a wet etching process, other suitable processes, or combinations thereof. For example, the etching process may be a wet etching process that utilizes an acid such as phosphoric acid (H₃PO₄), other suitable acids, or combinations thereof. In another embodiment, the etching process may include radical surface treatment. The air gap 680 exposes sidewalls of the backside source/drain contact 658 and the backside silicide feature 660. In a top view of the device 600, the air gap 680 fully surrounds the backside source/drain contact 658.

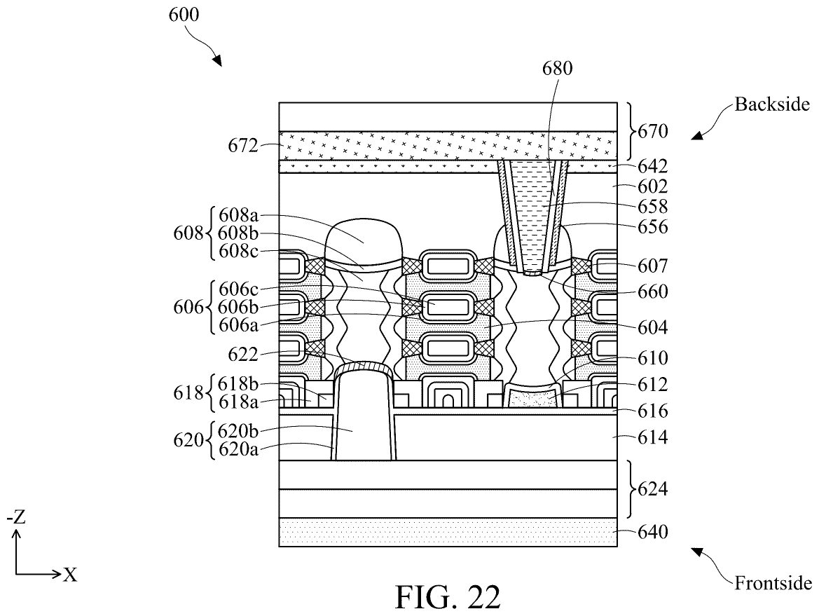

At operation 524, the method 500 (FIG. 8) forms one or more backside interconnect layers 670 with backside metal lines embedded in dielectric layers on the backside of the device 600, such as shown in FIG. 22. In the illustrated embodiment, the backside metal lines include a backside bit line 672 in a backside M0 interconnect layer that lands on the backside source/drain contact 658 and seals the air gap 680. Having the air gap 680 further reduces the parasitic capacitance loaded to the bit lines.

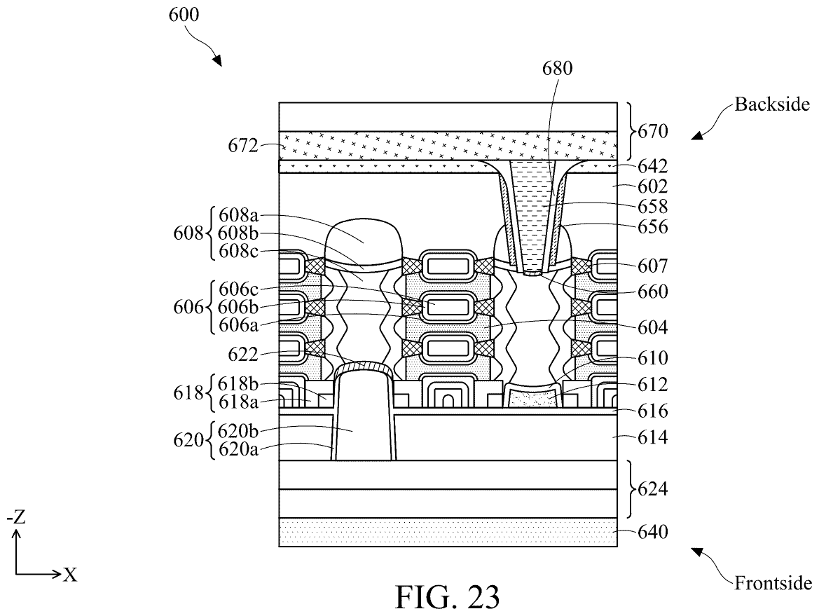

FIG. 23 illustrates an alternative embodiment of the device 600 at the conclusion of operations 524. In the depicted embodiment, due to limited etching contrast when removing the sacrificial liner 674, sidewalls of the dielectric liner 656 facing the air gap 680 may suffer some etching lost and exhibit a tapering profile, such that opening of the air gap 680 in proximity to the backside bit line 672 may have a larger width than a width of a middle portion of the air gap 680. A portion of the hard mask layer 642 may also be exposed in the air gap 680, in the depicted embodiment.

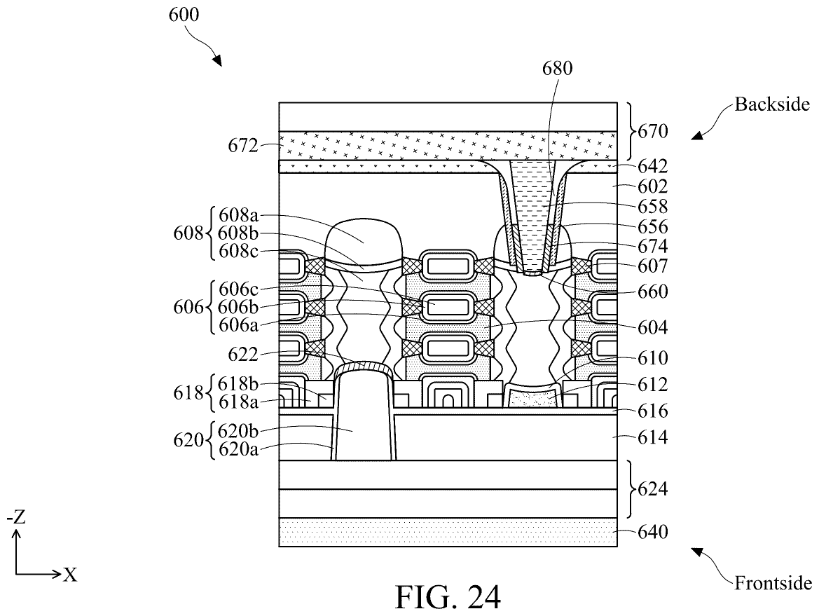

FIG. 24 illustrates another alternative embodiment of the device 600 at the conclusion of operations 524. In the depicted embodiment, due to the high aspect ratio of the sacrificial liner 674, the selective etching of the sacrificial liner 674 may not fully remove the sacrificial liner 674, such that a portion of the sacrificial liner 674 remains wrapping around a top portion of the backside source/drain contact 658 and covers the backside silicide feature 660. The air gap 680 may be below a bottom surface of the buffer epitaxial layer 608a. In some embodiments, a ratio of the height of the air gap 680 to the height of the backside source/drain contact 658 may range from about 0.3 to about 0.7.

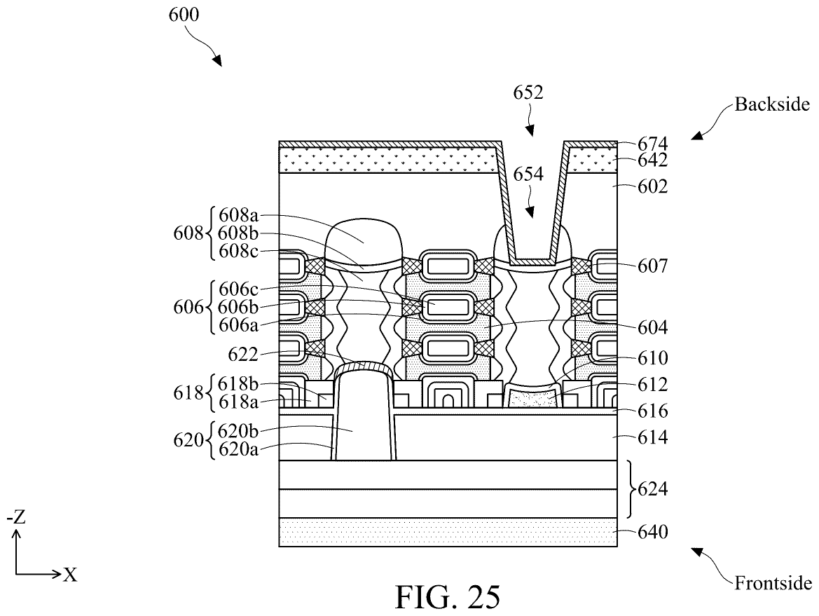

In some alternative embodiments, after operation 510, the method 500 (FIG. 8) may proceed directly to operation 516 in forming a sacrificial liner and skip operations 512 and 514 in forming a dielectric liner, which will be discussed in further detail below. At operation 516, the method 500 (FIG. 8) forms the sacrificial liner 674 on sidewalls and bottom surface of the backside contact hole 654 (including on backside surface of the device 600), such as shown in FIG. 25. In one example, the sacrificial liner 674 includes an oxide (e.g., silicon oxide) or a nitride (e.g., silicon nitride). In another example, the sacrificial liner 674 includes a semiconductor material, such as silicon (Si). In furtherance of the example, the sacrificial liner 674 may include amorphous silicon. In the illustrated embodiment, the sacrificial liner 674 is conformally deposited to have a substantially uniform thickness along the various surfaces of the backside of the device 600. The thickness of the sacrificial liner 674 sufficiently allows later forming an air gap with a meaningful volume after the selective removal of the sacrificial liner 674 to further effectively reduce parasitic capacitance loaded to the bit lines. The sacrificial liner 674 may be deposited using ALD, CVD, or other suitable methods.

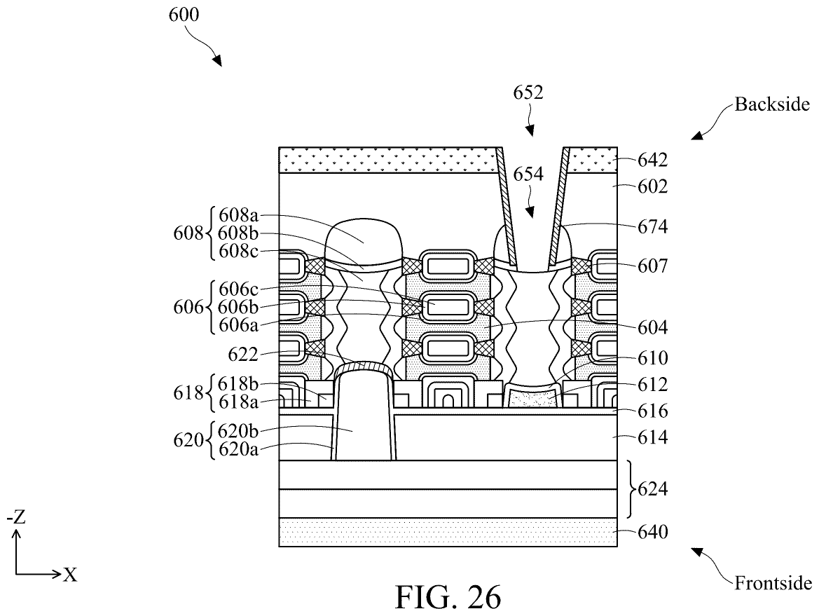

At operation 518, the method 500 (FIG. 8) performs an etching process for breaking through, and removing the majority of, the horizontal portions of the sacrificial liner 674, such as shown in FIG. 26. The etching process is also referred to as a breakthrough (BT) etching process. In some embodiments, the BT etching process may include an anisotropic dry etch process, or the like. In the illustrated embodiment, as a result of the operation 518, portions of the sacrificial liner 674 remain on sidewalls of the backside contact hole 654. The sacrificial liner 684 may also be in contact with the buffer epitaxial layer 608a and the blanket nitride layer 608b in the depicted embodiment. After the BT etching process, the blanket nitride layer 608b as an etch stop layer is exposed in the backside contact hole 654. Subsequently, an etching process is applied to remove the exposed portion of the blanket nitride layer 608b. The etching process(es) can be dry etching, wet etching, reactive ion etching, or other etching methods. At the conclusion of operation 518, the backside contact hole 654 exposes the bottom surface of the doped epitaxial layer 608c of the source/drain feature 260 from the backside. A portion of the blanket nitride layer 608b remains between the doped epitaxial layer 608c and the sacrificial liner 674. The bottom surface of the doped epitaxial layer 608c may have a concave profile bending towards the frontside of the device 600.

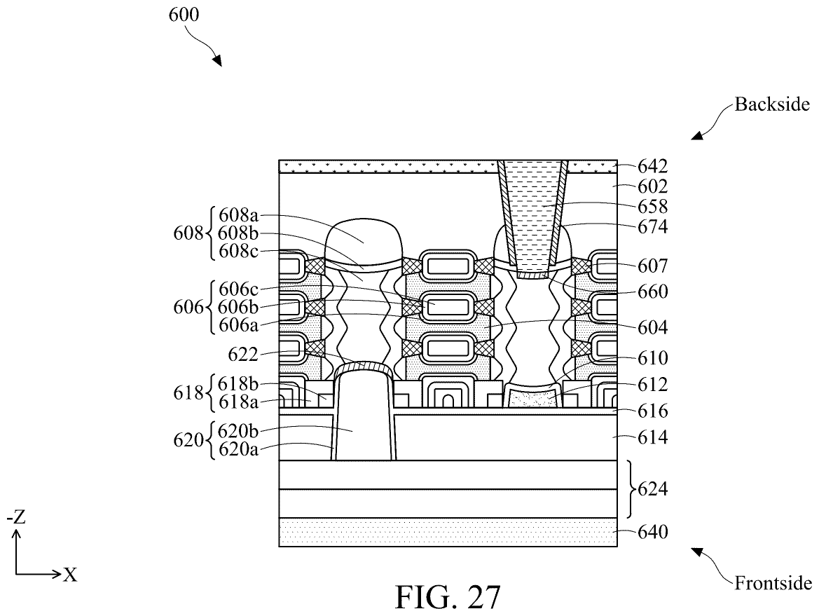

At operation 520, the method 500 (FIG. 8) forms the backside silicide feature 660 and the backside source/drain contact 658 in the backside contact hole 654, as shown in FIG. 27. A planarization operation, such as a chemical mechanical polishing (CMP) process, may also be performed to remove excessive conductive material and expose the backside of the hard mask layer 642. The sacrificial liner 674 separates the backside silicide feature 660 and the backside source/drain contact 658 from contacting the buffer epitaxial layer 608a. In some embodiments, the formation of the backside silicide feature 660 may be omitted, and the backside source/drain contact 658 may be in physical contact with the source/drain feature 608.

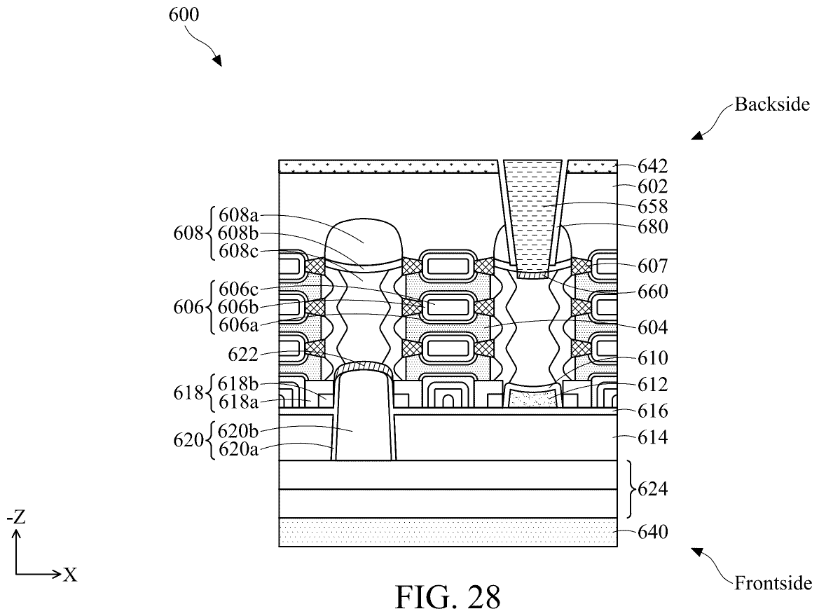

At operation 522, the method 500 (FIG. 8) selectively removes the sacrificial liner 674 from the backside of the device 600 to form the air gap 680, such as shown in FIG. 28. An etching process is performed to selectively remove the sacrificial liner 674. The air gap 680 tracks the shape of the sacrificial liner 674. The etching process may include a dry etching process, a wet etching process, other suitable processes, or combinations thereof. For example, the etching process may be a wet etching process that utilizes an acid such as phosphoric acid (H₃PO₄), other suitable acids, or combinations thereof. In another embodiment, the etching process may include radical surface treatment. The air gap 680 exposes sidewalls of the backside source/drain contact 658 and the buffer epitaxial layer 608a, as well as portions of the top surface of the blanket nitride layer 608b. In a top view of the device 600, the air gap 680 fully surrounds the backside source/drain contact 658.

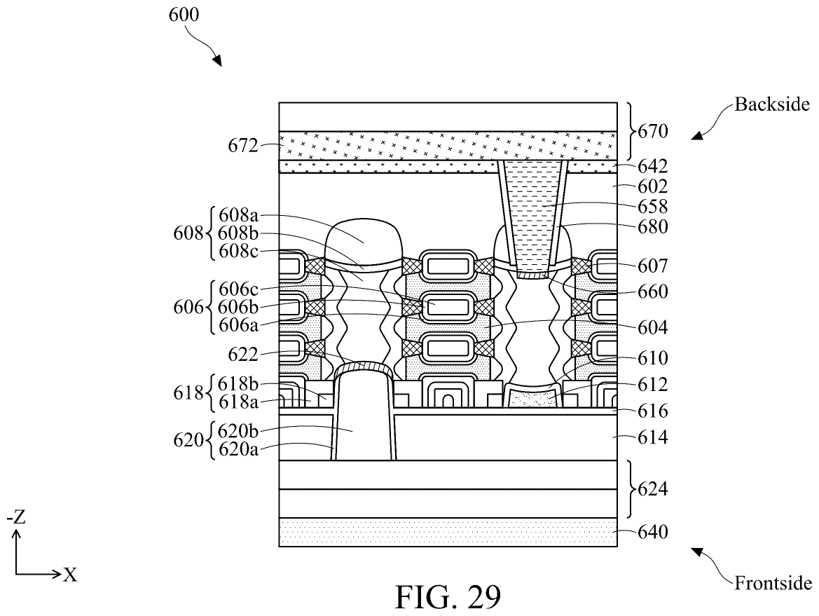

At operation 524, the method 500 (FIG. 8) forms one or more backside interconnect layers 670 with backside metal lines embedded in dielectric layers on the backside of the device 600, such as shown in FIG. 29. In the illustrated embodiment, the backside metal lines include a backside bit line 672 in a backside M0 interconnect layer that lands on the backside source/drain contact 658 and seals the air gap 680. Having the air gap 680 further reduces the parasitic capacitance loaded to the bit lines.

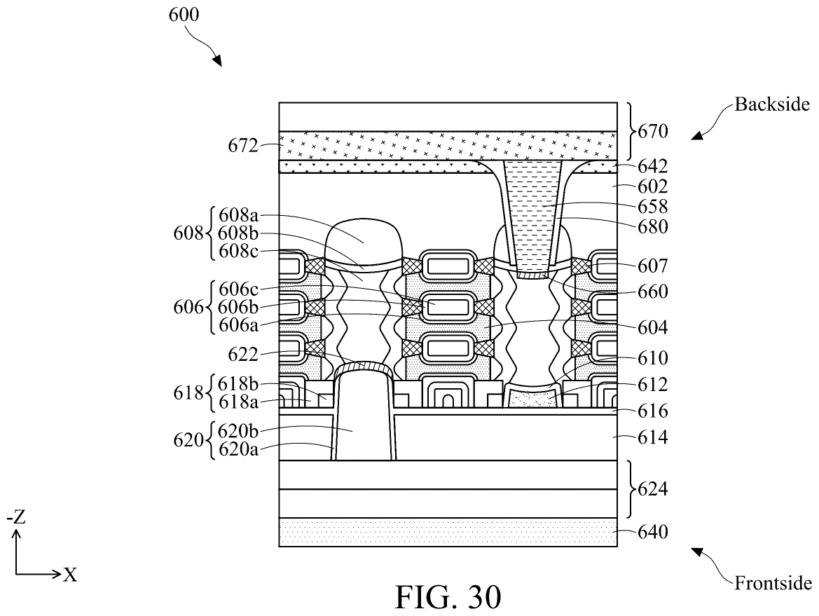

FIG. 30 illustrates an alternative embodiment of the device 600 at the conclusion of operations 524. In the depicted embodiment, due to limited etching contrast when removing the sacrificial liner 674, sidewalls of the substrate 602 and the hard mask layer 642 facing the air gap 680 may suffer some etching lost and exhibit a tapering profile, such that opening of the air gap 680 in proximity to the backside bit line 672 may have a larger width than a width of a middle portion of the air gap 680.

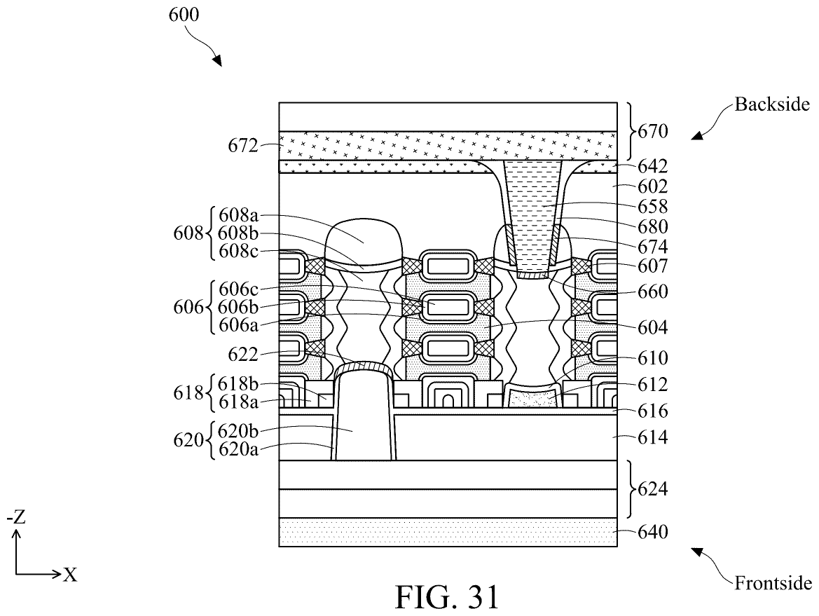

FIG. 31 illustrates another alternative embodiment of the device 600 at the conclusion of operations 524. In the depicted embodiment, due to the high aspect ratio of the sacrificial liner 674, the selective etching of the sacrificial liner 674 may not fully remove the sacrificial liner 674, such that a portion of the sacrificial liner 674 remains wrapping around a top portion of the backside source/drain contact 658 and covers the blanket nitride layer 608b. In some embodiments, a ratio of the height of the air gap 680 to the height of the backside source/drain contact 658 may range from about 0.3 to about 0.7. Depending on the remaining height of the sacrificial liner 674, a portion of the sidewall of the buffer epitaxial layer 608a may be exposed in the air gap 680 or remain being fully covered by the sacrificial liner 674.

The SRAM cells and the corresponding layouts illustrated in various exemplary embodiments of the present disclosure provide backside source/drain contacts for bit lines. The backside source/drain contacts together with the bit lines relocated to the backside of the memory device reduce the parasitic capacitance between the bit lines and the gate structures, which in turn improves circuit performance and enlarges process windows. Further, embodiments of the present disclosure can be readily integrated into existing semiconductor manufacturing processes.

In one exemplary aspect, the present disclosure is directed to a memory cell. The memory cell includes an active region extending lengthwise along a first direction, and first and second gate structures extending lengthwise along a second direction different from the first direction. The first gate structure engages the active region in forming a first transistor, the second gate structure engages the active region in forming a second transistor. The memory cell also includes a first epitaxial feature disposed on a source region of the first transistor, a second epitaxial feature disposed on a common drain region of the first and second transistors, a backside contact disposed under and in electrical coupling with the first epitaxial feature, a backside signal line disposed under and in electrical coupling with the backside contact, and a first frontside contact disposed above and in electrical coupling with the second epitaxial feature. In some embodiments, the backside signal line is a bit line of the memory cell. In some embodiments, the first and second transistors have a same conductivity type. In some embodiments, the first transistor is a pass-gate transistor of the memory cell, and the second transistor is a pull-down transistor of the memory cell. In some embodiments, the memory cell further includes a third epitaxial feature disposed on a source region of the second transistor, a second frontside contact directly above and in electrical coupling with the third epitaxial feature, and a frontside power line disposed directly above and in electrical coupling with the third epitaxial feature. In some embodiments, the frontside power line is a ground line of the memory cell. In some embodiments, a width of the backside signal line is larger than a width of the frontside power line. In some embodiments, the memory cell further includes a gate contact disposed directly above and in electrical coupling with the first gate structure, and a frontside signal line disposed directly above and in electrical coupling with the gate contact. In some embodiments, the frontside signal line is a word line of the memory cell. In some embodiments, the memory cell further includes a backside air gap surrounding the backside contact.

In another exemplary aspect, the present disclosure is directed to a memory array. The memory array includes first and second active regions extending lengthwise in a first direction, and a gate structure extending lengthwise along a second direction different from the first direction. The gate structure engages the first active region in forming a first transistor of a first memory cell and engages the second active region in forming a second transistor of a second memory cell, the first memory cell abuts the second memory cell along the second direction. The memory array also includes a first epitaxial feature disposed on a source/drain region of the first transistor, a second epitaxial feature disposed on a source/drain region of the second transistor, a first backside contact disposed under and in electrical coupling with the first epitaxial feature, a second backside contact disposed under and in electrical coupling with the second epitaxial feature, and a gate contact disposed above and in electrical coupling with the gate structure and positioned between the first and second active regions along the second direction. In some embodiments, the first backside contact is electrically coupled to a bit line of the first memory cell, the second backside contact is electrically coupled to a bit line of the second memory cell, and the gate contact is coupled to a word line of the memory array. In some embodiments, the memory array further includes a first backside bit line disposed directly under and in electrical coupling with the first backside contact, and a second backside bit line disposed directly under and in electrical coupling with the second backside contact. The first and second backside bit lines extend parallel to each other. In some embodiments, the memory array further includes a backside bit line disposed directly under and in electrical coupling with both the first and second backside contacts. In some embodiments, the memory array further includes a frontside word line disposed directly above and in electrical coupling with the gate contact. A width of the backside bit line is larger than a width of the frontside word line. In some embodiments, the memory array further includes a first backside air gap surrounding the first backside contact, and a second backside air gap surrounding the second backside contact.

In yet another exemplary aspect, the present disclosure is directed to a method of manufacturing a semiconductor device. The method includes forming a plurality of channel layers vertically stacked above a substrate, forming a gate structure wrapping around each of the channel layers, forming first and second epitaxial features sandwiching the channel layers, forming a frontside contact landing on a top surface of the first epitaxial feature, thinning the substrate from a backside of the semiconductor device, recessing a portion of the substrate to form a backside contact hole, the backside contact hole exposing a bottom surface of the second epitaxial feature, depositing a dielectric liner on sidewall of the backside contact hole, depositing a sacrificial liner over the dielectric liner, depositing a backside contact in the backside contact hole, the backside contact in electrical coupling with the second epitaxial feature, and selectively etching the sacrificial liner to form an air gap surrounding the backside contact, and depositing a backside metal line capping the air gap. In some embodiments, the backside metal line is a bit line of a memory cell. In some embodiments, the sacrificial liner includes amorphous silicon. In some embodiments, the method further includes forming a silicide feature stacked between the backside contact and the second epitaxial feature. After the selectively etching of the sacrificial liner, a remaining portion of the sacrificial liner covers the silicide feature from being exposed in the air gap.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory cell, comprising:
an active region extending lengthwise along a first direction;
first and second gate structures extending lengthwise along a second direction different from the first direction, wherein the first gate structure engages the active region in forming a first transistor, the second gate structure engages the active region in forming a second transistor;
a first epitaxial feature disposed on a source region of the first transistor;
a second epitaxial feature disposed on a common drain region of the first and second transistors;
a backside contact disposed under and in electrical coupling with the first epitaxial feature;
a backside signal line disposed under and in electrical coupling with the backside contact; and
a first frontside contact disposed above and in electrical coupling with the second epitaxial feature.

2. The memory cell of claim 1, wherein the backside signal line is a bit line of the memory cell.

3. The memory cell of claim 1, wherein the first and second transistors have a same conductivity type.

4. The memory cell of claim 1, wherein the first transistor is a pass-gate transistor of the memory cell, and the second transistor is a pull-down transistor of the memory cell.

5. The memory cell of claim 1, further comprising:
a third epitaxial feature disposed on a source region of the second transistor;
a second frontside contact above and in electrical coupling with the third epitaxial feature; and
a frontside power line disposed above and in electrical coupling with the third epitaxial feature.

6. The memory cell of claim 5, wherein the frontside power line is a ground line of the memory cell.

7. The memory cell of claim 5, wherein a width of the backside signal line is larger than a width of the frontside power line.

8. The memory cell of claim 1, further comprising:
a gate contact disposed above and in electrical coupling with the first gate structure; and
a frontside signal line disposed above and in electrical coupling with the gate contact.

9. The memory cell of claim 8, wherein the frontside signal line is a word line of the memory cell.

10. The memory cell of claim 1, further comprising:
a backside air gap surrounding the backside contact.

11. A memory array, comprising:
first and second active regions extending lengthwise in a first direction;
a gate structure extending lengthwise along a second direction different from the first direction, wherein the gate structure engages the first active region in forming a first transistor of a first memory cell and engages the second active region in forming a second transistor of a second memory cell, the first memory cell abuts the second memory cell along the second direction;
a first epitaxial feature disposed on a source/drain region of the first transistor;
a second epitaxial feature disposed on a source/drain region of the second transistor;
a first backside contact disposed under and in electrical coupling with the first epitaxial feature;
a second backside contact disposed under and in electrical coupling with the second epitaxial feature; and
a gate contact disposed above and in electrical coupling with the gate structure and positioned between the first and second active regions along the second direction.

12. The memory array of claim 11, wherein the first backside contact is electrically coupled to a bit line of the first memory cell, the second backside contact is electrically coupled to a bit line of the second memory cell, and the gate contact is coupled to a word line of the memory array.

13. The memory array of claim 11, further comprising:
a first backside bit line disposed directly under and in electrical coupling with the first backside contact; and
a second backside bit line disposed directly under and in electrical coupling with the second backside contact, wherein the first and second backside bit lines extend parallel to each other.

14. The memory array of claim 11, further comprising:
a backside bit line disposed directly under and in electrical coupling with both the first and second backside contacts.

15. The memory array of claim 14, further comprising:
a frontside word line disposed directly above and in electrical coupling with the gate contact, wherein a width of the backside bit line is larger than a width of the frontside word line.

16. The memory array of claim 11, further comprising:
a first backside air gap surrounding the first backside contact; and
a second backside air gap surrounding the second backside contact.

17. A method of manufacturing a semiconductor device, comprising:
forming a plurality of channel layers vertically stacked above a substrate;
forming a gate structure wrapping around each of the channel layers;
forming first and second epitaxial features sandwiching the channel layers;
forming a frontside contact landing on a top surface of the first epitaxial feature;
thinning the substrate from a backside of the semiconductor device;
recessing a portion of the substrate to form a backside contact hole, the backside contact hole exposing a bottom surface of the second epitaxial feature;
depositing a dielectric liner on sidewall of the backside contact hole;
depositing a sacrificial liner over the dielectric liner;
depositing a backside contact in the backside contact hole, the backside contact in electrical coupling with the second epitaxial feature; and
selectively etching the sacrificial liner to form an air gap surrounding the backside contact; and
depositing a backside metal line capping the air gap.

18. The method of claim 17, wherein the backside metal line is a bit line of a memory cell.

19. The method of claim 17, wherein the sacrificial liner includes amorphous silicon.

20. The method of claim 17, further comprising:
forming a silicide feature stacked between the backside contact and the second epitaxial feature,
wherein after the selectively etching of the sacrificial liner, a remaining portion of the sacrificial liner covers the silicide feature from being exposed in the air gap.
